(19) United States
(12) Patent Application Publication
(10) Pub. No.: US 2026/0164970 A1
(43) Pub. Date: Jun. 11, 2026

(54) DISPLAY PANEL INCLUDING INTERCONNECT STRUCTURE AND ELECTRONIC APPARATUS INCLUDING DISPLAY PANEL

(71) Applicant: Samsung Display Co., Ltd., Yongin-si (KR)

(72) Inventors: Yunjong Yeo, Yongin-si (KR); Dawoon Jung, Yongin-si (KR); Jungyun Jo, Yongin-si (KR); Daewon Choi, Yongin-si (KR)

(21) Appl. No.: 19/413,113

(22) Filed: Dec. 9, 2025

(30) Foreign Application Priority Data
Dec. 9, 2024 (KR) 10-2024-0181955

(51) Int. Cl. H10K 59/131

(52) U.S. Cl. CPC H10K 59/131

(57) ABSTRACT

A display panel includes a circuit layer between a substrate and a light emitting diode. The circuit layer includes an interconnect structure including a first conductive material layer, a first insulating layer over the first conductive material layer, a first conductor including a side part and a lower part, where the side part is on an inner wall of the first insulating layer defining a first contact hole, and the lower part is integrally formed with the side part and directly contacts a portion of the upper surface of the first conductive material layer, an inorganic filler in a recess surrounded by the side part and including an inorganic insulating material, a second insulating layer over the first insulating layer, and a second conductor directly contacting an upper surface of the side part of the first conductor through a second contact hole in the second insulating layer.

This application claims priority to Korean Patent Application No. 10-2024-0181955, filed on Dec. 9, 2024, and all the benefits accruing therefrom under 35 U.S.C. § 119, the content of which in its entirety is herein incorporated by reference.

### BACKGROUND

### 1. Field

One or more embodiments relate to a method of manufacturing an interconnect structure, a display panel including the interconnect structure, and an electronic apparatus including the display panel.

### 2. Description of the Related Art

Recently, display panels have been used in various electronic apparatuses. As display panels have been widely used, the demand for high-resolution display panels and various shapes of display panels has increased and research on the utilization of the space of display panels has been continuously conducted to implement high-resolution display panels.

### SUMMARY

A sufficient space may be desired to design a high-resolution display panel, and for this purpose, the area occupied by a contact structure for electrical connection of two components may be desired to be reduced. Accordingly, one or more embodiments include a method of forming a connection structure suitable for high resolution through a minimum process, a display panel including the connection structure, and an electronic apparatus including the display panel.

According to one or more embodiments, a display panel includes a substrate, a light emitting diode arranged over the substrate, and a circuit layer arranged between the substrate and the light emitting diode, where the circuit layer includes an interconnect structure including a first conductive material layer arranged over the substrate, a first insulating layer arranged over the first conductive material layer, where a first contact hole is defined in the first insulating layer to overlap a portion of an upper surface of the first conductive material layer, a first conductor including a side part and a lower part, where the side part is on an inner wall of the first insulating layer defining the first contact hole, and the lower part is integrally formed with the side part as a single unitary indivisible part and directly contacts a portion of the upper surface of the first conductive material layer, an inorganic filler arranged in a recess surrounded by the side part of the first conductor in the first contact hole, where the inorganic filler includes an inorganic insulating material, a second insulating layer arranged over the first insulating layer, where a second contact hole is defined in the second insulating layer to overlap the first contact hole, and a second conductor directly contacting an upper surface of the side part of the first conductor through the second contact hole of the second insulating layer.

In an embodiment, the second insulating layer may include an inorganic insulating material, and the inorganic insulating material of the second insulating layer may be the same as the inorganic insulating material of the inorganic filler.

In an embodiment, the side part of the first conductor may be in direct contact with the inner wall of the first insulating layer, and a first point, at which the side part of the first conductor and the inner wall of the first insulating layer contact each other, may be spaced apart by a first distance along the inner wall from a second point, at which the inner wall of the first insulating layer and an upper surface of the first insulating layer meet each other.

In an embodiment, the upper surface of the side part of the first conductor may be located on an imaginary plane parallel to an upper surface of the substrate.

In an embodiment, the upper surface of the side part of the first conductor may be inclined with respect to an imaginary plane parallel to an upper surface of the substrate.

In an embodiment, the second conductor may be direct contact with an upper surface of the inorganic filler.

In an embodiment, the display panel may further include a third insulating layer over the second insulating layer, where a third contact hole may be defined in the third insulating layer and overlap the second contact hole.

In an embodiment, the first conductor may include a first first conductor including a first side part and a first lower part, where the first side part directly contacts an inner wall of the first insulating layer defining the first contact hole, and the first lower part is integrally formed with the first side part as a single unitary indivisible part and directly contacts a portion of the upper surface of the first conductive material layer, and a second first conductor including a second side part and a second lower part, where the second side part directly contacts the first side part of the first first conductor, and the second lower part directly contacts the first lower part, where the inorganic filler may be surrounded by the second side part of the second first conductor.

In an embodiment, the circuit layer may further include a transistor arranged over the substrate, where the transistor may include a semiconductor layer and a gate electrode, and a capacitor including a first electrode and a second electrode which overlap each other, where the first conductive material layer may define one of the semiconductor layer, the gate electrode, the first electrode, and the second electrode.

In an embodiment, a contact area of the second conductor and the first conductor may have a closed-loop shape in a plan view.

In an embodiment, a width of an upper portion of the first contact hole measured by using a point, at which an upper surface and the inner wall of the first insulating layer meet each other, may be greater than a width of an upper surface of the inorganic filler and may be less than a width of a lower portion of the second contact hole measured by using a point, at which an inner wall of the second insulating layer and the upper surface of the first insulating layer meet each other.

According to one or more embodiments, a method of manufacturing a display panel including a substrate, a light emitting diode arranged over the substrate, and a circuit layer arranged between the substrate and the light emitting diode and including an interconnect structure is provided. In such embodiments, the method of manufacturing the display panel includes a method of manufacturing an interconnect structure. In such embodiments, the method of manufacturing the interconnect structure includes forming a first conductive material layer over the substrate, forming a first insulating layer on the first conductive material layer, where a first contact hole is formed in the first insulating layer to overlap a portion of an upper surface of the first conductive material layer, forming a first conductor in the first contact hole, where the first conductor includes a side part and a lower part, where the side part is on an inner wall of the first insulating layer defining the first contact hole, and the lower part is integrally formed with the side part as a single unitary indivisible part and directly contacts a portion of the upper surface of the first conductive material layer, forming an inorganic filler in a recess surrounded by the side part of the first conductor, in the first contact hole, where the inorganic filler includes an inorganic insulating material, and forming a second conductor directly contacting an upper surface of the side part of the first conductor.

In an embodiment, the forming the inorganic filler may include forming an insulating material layer over an upper surface of the first insulating layer and an upper surface of the side part of the first conductor to at least partially fill the recess, and removing a portion of the insulating material layer which overlaps the first contact hole while leaving a portion of the insulating material layer which is in the recess corresponding to the inorganic filler, where the insulating material layer is removed in a way such that a second insulating layer may be formed over the upper surface of the first insulating layer, and a second contact hole overlapping the first contact hole may be defined in the second insulating layer.

In an embodiment, the second conductor may be in direct contact with an upper surface of the side part of the first conductor through the second contact hole of the second insulating layer.

In an embodiment, a contact area of the second conductor and the first conductor may have a closed-loop shape in a plan view.

In an embodiment, the forming the first conductor may include a process of forming a conductive layer over an upper surface of the first insulating layer, the inner wall of the first insulating layer, and a portion of the upper surface of the first conductive material layer, forming a planarization layer including an organic material to fill a recess surrounded by a portion of the conductive layer formed on the inner wall of the first insulating layer, etching back the planarization layer, removing a portion of the conductive layer which is on the upper surface of the first insulating layer while leaving a portion of the conductive layer which is inside the first contact hole corresponding to the first conductor, and removing residue of the planarization layer in the recess.

In an embodiment, the etching back the planarization layer and the removing a portion of the conductive layer may be performed in a same etching process.

In an embodiment, the side part of the first conductor may be in direct contact with the inner wall of the first insulating layer, and a first point, at which the side part of the first conductor and the inner wall of the first insulating layer contact each other, may be spaced apart by a first distance along the inner wall from a second point, at which the inner wall of the first insulating layer and an upper surface of the first insulating layer meet each other.

In an embodiment, the upper surface of the side part of the first conductor may be located on an imaginary plane parallel to an upper surface of the substrate.

In an embodiment, the upper surface of the side part of the first conductor may be inclined with respect to an imaginary plane parallel to an upper surface of the substrate.

According to one or more embodiments, an electronic apparatus includes a display panel according to the above embodiments and a lower cover supporting the display panel.

According to one or more embodiments, an electronic apparatus includes a display panel with a resolution of 1500 pixels per inch (ppi) or greater, where the display panel includes a substrate, a light emitting diode arranged over the substrate, a circuit layer arranged between the substrate and the light emitting diode. In such embodiments, the circuit layer includes an interconnection structure including a first conductive material layer arranged over the substrate, a first insulating layer arranged over the first conductive material layer, where a first contact hole is defined in the first insulating layer to overlap a portion of an upper surface of the first conductive material layer, a first conductor electrically connected to the first conductive material layer, arranged in the first contact hole, and having a closed-loop shape in a plan view, a second insulating layer arranged over the first insulating layer, where a second contact hole is defined in the second insulating layer, and a second conductor directly contacting at least a portion of the first conductor through the second contact hole of the second insulating layer, where area of a contact area of the second conductor and the first conductor is in a range of about 0.039 square micrometer (μm²) to about 3.11 μm².

In an embodiment, the first conductor may include a side part and a lower part, where the side part is on an inner wall of the first insulating layer defining the first contact hole, and the lower part is integrally formed with the side part as a single unitary indivisible part and directly contacts a portion of the upper surface of the first conductive material layer, and the interconnection structure may further include an inorganic filler arranged in a recess surrounded by the side part of the first conductor in the first contact hole, where the inorganic filler includes an inorganic insulating material.

In an embodiment, the side part of the first conductor may be in direct contact with the inner wall of the first insulating layer, and a first point, at which the side part of the first conductor and the inner wall of the first insulating layer contact each other, may be spaced apart by a first distance along the inner wall from a second point, at which the inner wall of the first insulating layer and an upper surface of the first insulating layer meet each other.

In an embodiment, the upper surface of the side part of the first conductor may be located on an imaginary plane parallel to an upper surface of the substrate.

In an embodiment, the upper surface of the side part of the first conductor may be inclined with respect to an imaginary plane parallel to an upper surface of the substrate.

In an embodiment, the second insulating layer may include an inorganic insulating material, and the inorganic insulating material of the second insulating layer may be the same as the inorganic insulating material of the inorganic filler.

In an embodiment, the circuit layer may further include a transistor arranged over the substrate, where the transistor includes a semiconductor layer and a gate electrode, and a capacitor including a first electrode and a second electrode which overlap each other, where the first conductive material layer may define one of the semiconductor layer, the gate electrode, the first electrode, and the second electrode.

### BRIEF DESCRIPTION OF THE DRAWINGS

The above and other features of certain embodiments of the disclosure will be more apparent from the following description taken in conjunction with the accompanying drawings, in which:

FIG. 1 is a perspective view illustrating an electronic apparatus according to an embodiment;

FIG. 2 is an exploded perspective view illustrating an electronic apparatus according to an embodiment;

FIG. 3 is a block diagram illustrating an electronic apparatus according to an embodiment;

FIG. 4 is an equivalent circuit diagram schematically illustrating a light emitting diode of a display panel and a circuit connected to the light emitting diode, according to an embodiment;

FIG. 5 is a cross-sectional view illustrating a portion of a display panel according to an embodiment;

FIGS. 6A to 6I are cross-sectional views illustrating a process of forming an interconnect structure included in a circuit layer of a display panel according to an embodiment;

FIG. 7A is a plan view of a first conductor of FIG. 6E when viewed in a direction perpendicular to an upper surface of a substrate;

FIG. 7B is an enlarged cross-sectional view of region VIIb of FIG. 6E;

FIG. 8 is a cross-sectional view according to an embodiment of a process to be described with reference to FIG. 6F;

FIG. 9A is a plan view illustrating a contact structure of a second conductor and a first conductor according to a process described with reference to FIG. 6I;

FIG. 9B is a cross-sectional view of an interconnect structure according to a process according to an embodiment;

FIG. 9C is a plan view illustrating a contact structure of a second conductor and a first conductor according to a process according to an embodiment;

FIGS. 10A to 10G are cross-sectional views illustrating a process of forming an interconnect structure included in a circuit layer of a display panel according to an embodiment;

FIGS. 11A and 11B are cross-sectional views illustrating a process of forming a first conductor in a process of forming an interconnect structure included in a circuit layer of a display panel according to an embodiment;

FIG. 12 is a cross-sectional view illustrating an interconnect structure according to an embodiment; and

FIG. 13 is a perspective view illustrating an electronic apparatus according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b and c” or “at least one selected from a, b and c” indicates only a, only b, only c, both a and b, both a and c, both b and c, all of a, b, and c, or variations thereof.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element is referred to as being “on” another element, it can be directly on the other element or intervening elements may be present therebetween. In contrast, when an element is referred to as being “directly on” another element, there are no intervening elements present.

Sizes of components in the drawings may be exaggerated for convenience of description. In other words, because the sizes and shapes of components in the drawings are arbitrarily illustrated for convenience of description, the disclosure is not limited thereto.

When a certain embodiment may be implemented differently, a particular process order may be performed differently from the described order. For example, two consecutively described processes may be performed substantially at the same time or performed in an order opposite to the described order.

It will be understood that when a layer, region, area, component, or element is referred to as being “connected to” another layer, region, area, component, or element, it may be “directly connected to” the other layer, region, area, component, or element or may be “indirectly connected to” the other layer, region, area, component, or element with one or more intervening layers, regions, areas, components, or elements therebetween. For example, it will be understood that when a layer, region, or component is referred to as being “electrically connected to” another layer, region, or component, it may be “directly electrically connected to” the other layer, region, or component or may be “indirectly electrically connected to” the other layer, region, or component with one or more intervening layers, regions, or components therebetween.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, ±20%, ±10% or ±5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings, and in the following description, like reference numerals will denote like elements and redundant descriptions thereof will be omitted for conciseness.

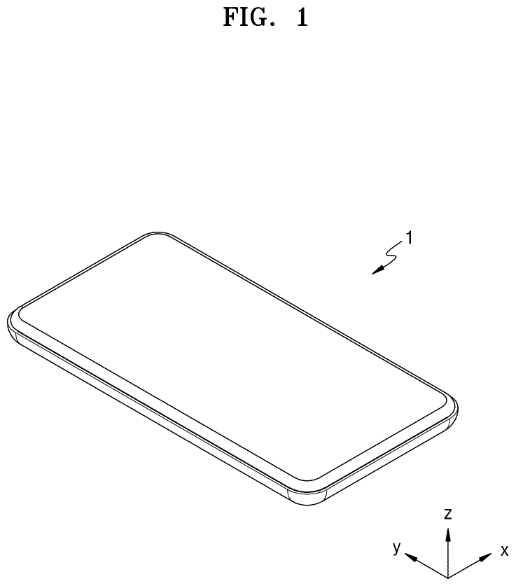

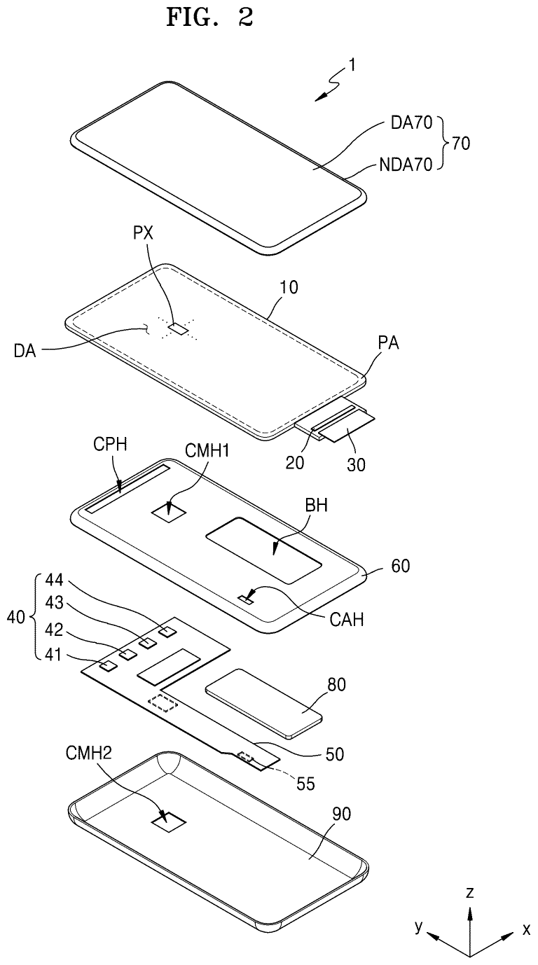

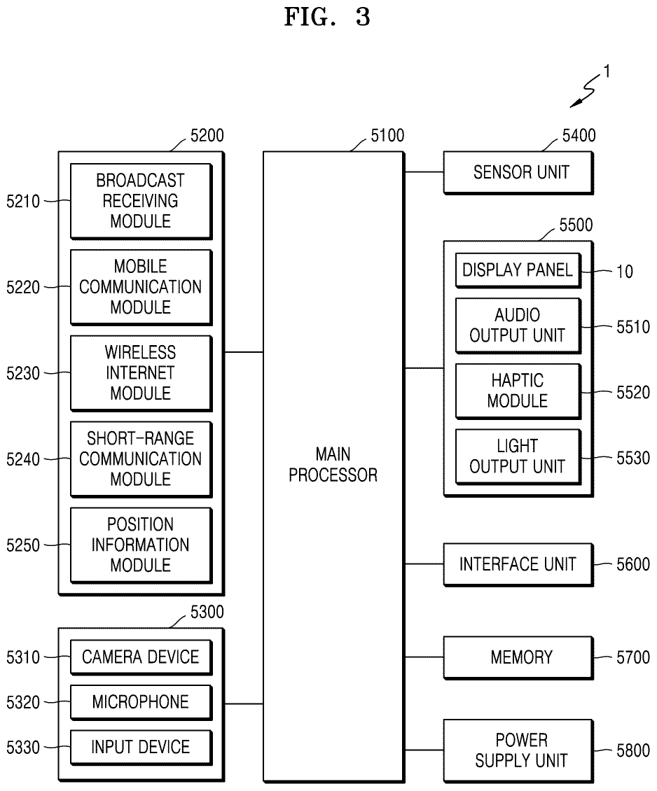

FIG. 1 is a perspective view illustrating an electronic apparatus 1 according to an embodiment, FIG. 2 is an exploded perspective view illustrating an electronic apparatus 1 according to an embodiment, and FIG. 3 is a block diagram illustrating an electronic apparatus 1 according to an embodiment.

Referring to FIG. 1 and FIG. 2, the electronic apparatus 1 according to an embodiment may be an apparatus that displays moving images or still images. FIG. 1 illustrates an embodiment where the electronic apparatus 1 is a smart phone. In such an embodiment, the electronic apparatus 1 may include a cover window 70, a display panel 10, a data driver 20, a display circuit board 30, a component 40, a bracket 60, a main circuit board 50, a battery 80, and a lower cover 90.

In a plan view herein, “left,” “right,” “up,” and “down” may refer to directions when viewing the display panel 10 in a vertical direction (or thickness direction) of the display panel 10. For example, “left” may refer to the −x direction, “right” may refer to the +x direction, “up” may refer to the +y direction, and “down” may refer to the −y direction.

The electronic apparatus 1 may have a rectangular shape in the plan view or when viewed in the z direction. In an embodiment, for example, the electronic apparatus 1 may have a rectangular planar shape having a short side in the x direction and a long side in the y direction as illustrated in FIG. 1. The corner, at which the short side in the x direction and the long side in the y direction meet each other, may be rounded with a certain curvature or formed at a right angle. The plane shape of the electronic apparatus 1 is not limited to a rectangular shape and may be any polygonal, elliptical, or atypical shape.

The cover window 70 may be arranged over the display panel 10 to cover the upper surface of the display panel 10. Accordingly, the cover window 70 may protect the upper surface of the display panel 10.

The cover window 70 may include a transparent cover unit DA70 corresponding to a display area DA of the display panel 10 and a light-blocking cover unit NDA70 surrounding the transparent cover unit DA70. The light-blocking cover unit NDA70 may include an opaque material (e.g., a colored opaque material) that blocks light. The light-blocking cover unit NDA70 may overlap a peripheral area PA of the display panel 10 in a plan view or when viewed in the z direction.

The display panel 10 may be arranged under the cover window 70. The display panel 10 may include a display area DA and a peripheral area PA around the display area DA. The display area DA may be an area where an image is displayed. In an embodiment, the display area DA may include an area (hereinafter referred to as a component area) that transmits light emitted from the component 40 arranged under the display panel 10. The component 40 may include a sensor or a camera that uses visible light, infrared light, or sound.

The display panel 10 may be a light emitting display panel including a light emitting diode. The light emitting diode may include an organic light emitting diode including an organic emission layer. The light emitting diode may be an inorganic light emitting diode including an inorganic material. The inorganic light emitting diode may include a PN junction diode including inorganic semiconductor-based materials. When a forward voltage is applied to the PN junction diode, holes and electrons may be injected thereinto and energy generated by the recombination of the holes and electrons may be converted into light energy to emit light of a certain color. The light emitting diode may be a light emitting diode including quantum dots.

The display panel 10 may be a rigid display panel that is rigid or a flexible display panel that is flexible and easily bent. In an embodiment, the display panel 10 may be assembled between the cover window 70 and the lower cover 90 while a portion of the peripheral area PA is bent.

In an embodiment, the data driver 20 may be arranged on the display panel 10 in the form of an integrated circuit (IC). In another embodiment, the data driver 20 may be arranged on the display circuit board 30.

The display circuit board 30 may be attached to one side of the display panel 10. The display circuit board 30 may be a flexible printed circuit board (FPCB) that may be bent, may be a rigid printed circuit board (rigid PCB) that is rigid and thus is not easily bent, or may be a composite PCB including both a rigid PCB and an FPCB.

In an embodiment, a touch sensor driver may be arranged on the display circuit board 30. The touch sensor driver may be formed as an integrated circuit. The touch sensor driver may be attached onto the display circuit board 30. The touch sensor driver may be electrically connected to touch electrodes of a touch screen layer of the display panel 10 through the display circuit board 30.

The touch screen layer of the display panel 10 may detect a user's touch input by using at least one of various touch methods such as a resistive method and a capacitive method. For example, when the touch screen layer of the display panel 10 detects a user's touch input by the capacitive method, the touch sensor driver may apply driving signals to driving electrodes among the touch electrodes and detect voltages charged in mutual electrostatic capacitances (hereinafter referred to as “mutual capacitances”) between driving electrodes and sensing electrodes through sensing electrodes among the touch electrodes, thereby determining whether a user's touch has occurred. The user's touch may include a contact touch and a proximity touch. The contact touch may mean that a user's finger or an object such as a pen directly contacts the cover window 70 arranged over the touch screen layer. The proximity touch may mean that a user's finger or an object such as a pen is located close to and apart from the cover window 70, such as hovering. The touch sensor driver may transmit sensor data to a main processor 5100 according to the detected voltages, and the main processor 5100 may calculate touch coordinates of the touch input by analyzing the sensor data.

A controller for supplying driving voltages for driving the data driver 20, a gate driver, and pixels of the display panel 10 may be arranged on the display circuit board 30.

The bracket 60 for supporting the display panel 10 may be arranged under the display panel 10. The bracket 60 may include plastic, metal, or both plastic and metal. The bracket 60 may be provided with a first camera hole CMH1 into which a camera device 5310 is inserted, a battery hole BH in which the battery 80 is arranged, and a cable hole CAH through which a cable connected to the display circuit board 30 passes. The bracket 60 may be provided with a component hole CPH overlapping the display panel 10. The component hole CPH may overlap the components 40 of the main circuit board 50 in a third direction (z direction). In an embodiment, the display area DA of the display panel 10 may overlap the components 40 of the main circuit board 50 in the third direction (z direction). In another embodiment, the bracket 60 may not be provided with the component hole CPH.

In an embodiment, the component 40 may include first to fourth components 41, 42, 43, and 44 that overlap the display panel 10. The first to fourth components 41, 42, 43, and 44 may be provided as a proximity sensor, an illumination sensor, an iris sensor, a face recognition sensor, or a camera (or an image sensor). The proximity sensor using infrared rays may detect an object arranged close to the upper surface of the electronic apparatus 1, and the illumination sensor may sense the brightness of light incident on the upper surface of the electronic apparatus 1. Also, the iris sensor may photograph a person's iris arranged over the upper surface of the electronic apparatus 1, and the camera may photograph an object arranged over the upper surface of the electronic apparatus 1. The component 40 is not limited to a proximity sensor, an illumination sensor, an iris sensor, a face recognition sensor, and a camera and may include other sensors described below.

The main circuit board 50 and the battery 80 may be arranged under the bracket 60. The main circuit board 50 may be a rigid PCB or an FPCB.

The main circuit board 50 may include a main processor 5100, a camera device 5310, a main connector 55, and components 40. The main processor 5100 may be formed as an integrated circuit. The camera device 5310 may be arranged on both the upper and lower surfaces of the main circuit board 50, and each of the main processor 5100 and the main connector 55 may be arranged on one of the upper and lower surfaces of the main circuit board 50.

The main processor 5100 may control all functions of the electronic apparatus 1. In an embodiment, for example, the main processor 5100 may output digital video data to the data driver 20 through the display circuit board 30 such that the display panel 10 displays an image. The main processor 5100 may receive sensing data from the touch sensor driver. The main processor 5100 may determine whether there is a user touch based on the sensing data and execute an operation corresponding to the user's direct touch or proximity touch. The main processor 5100 may be an application processor, a central processing unit, or a system chip including an integrated circuit.

The camera device 5310 may process an image frame such as a still image or a moving image obtained by an image sensor in a camera mode and output the processed image frame to the main processor 5100. The camera device 5310 may include at least one selected from a camera sensor (e.g., charge-coupled device (CCD) or complementary metal oxide semiconductor (CMOS) sensor), a photo sensor (or an image sensor), and a laser sensor. The camera device 5310 may be connected to an image sensor among the components 40 overlapping the display area DA, to process an image input by the image sensor.

A cable passing through the cable hole CAH of the bracket 60 may be connected to the main connector 55, and thus, the main circuit board 50 may be electrically connected to the display circuit board 30.

In addition to the main processor 5100, the camera device 5310, and the main connector 55, the main circuit board 50 may further include a wireless communicator 5200, an input unit 5300, a sensor unit 5400, an output unit 5500, an interface unit 5600, a memory 5700, and/or a power supply unit 5800 as illustrated in FIG. 3.

The wireless communicator 5200 may include at least one selected from a broadcast receiving module 5210, a mobile communication module 5220, a wireless Internet module 5230, a short-range communication module 5240, and a position information module 5250.

The broadcast receiving module 5210 may receive broadcast signals and/or broadcast-related information from an external broadcast management server through broadcast channels. The broadcast channels may include satellite channels and terrestrial channels.

The mobile communication module 5220 may transmit/receive wireless signals to/from at least one of a base station, an external terminal, and a server in a mobile communication network established according to technology standards or communication methods for mobile communication (e.g., Global System for Mobile communication (GSM), Code Division Multi Access (CDMA), Code Division Multi Access 2000 (CDMA 2000 ), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), and Long Term Evolution-Advanced (LTE-A)). The wireless signals may include various forms of data according to voice call signals, video call signals, or text/multimedia message transmission/reception.

The wireless Internet module 5230 may refer to a module for wireless Internet access. The wireless Internet module 5230 may be configured to transmit/receive wireless signals in a communication network according to wireless Internet technologies. The wireless Internet technologies may include, for example, Wireless LAN (WLAN), Wireless Fidelity (WiFi), WiFi Direct, and/or Digital Living Network Alliance (DLNA).

The short-range communication module 5240 may be for short-range communication and may support short-range communication by using at least one selected from Bluetooth™, Radio Frequency Identification (RFID), Infrared Data Association (IrDA), Ultra Wideband (UWB), ZigBee, Near Field Communication (NFC), Wireless Fidelity (WiFi), WiFi Direct, and Wireless Universal Serial Bus (Wireless USB) technologies. The short-range communication module 5240 may support wireless communication between the electronic apparatus 1 and a wireless communication system, between the electronic apparatus 1 and another electronic apparatus, or between the electronic apparatus 1 and a network in which another electronic apparatus (or an external server) is located, through a short-range wireless communication network (Wireless Area Network). The short-range wireless communication network may be a short-range wireless personal area network (Wireless Personal Area Network). The other electronic apparatus may be a wearable device capable of exchanging data (or capable of interoperating) with the electronic apparatus 1.

The position information module 5250 may be a module for obtaining the position (or current position) of the electronic apparatus 1 and may include a Global Positioning System (GPS) module or a WiFi module.

The input unit 5300 may include an image input unit such as a camera device 5310 for inputting an image signal, an audio input unit such as a microphone 5320 for inputting an audio signal, and an input device 5330 for receiving information from the user.

The camera device 5310 may process an image frame such as a still image or a moving image obtained by an image sensor in a video call mode or a photographing mode. The processed image frame may be displayed on the display panel 10 or stored in the memory 5700.

The microphone 5320 may process an external audio signal into electrical voice data. The processed voice data may be variously used depending on the functions performed (or the applications executed) in the electronic apparatus 1.

The main processor 5100 may control the operation of the electronic apparatus 1 to correspond to information input through the input device 5330. The input device 5330 may include a mechanical input unit or a touch input unit such as a button, a dome switch, a jog wheel, or a jog switch located on the rear surface or side surface of the electronic apparatus 1. The touch input unit may include (or be defined by) a touch screen layer of the display panel 10.

The sensor unit 5400 may include one or more sensors that sense at least one selected from information in the electronic apparatus 1, information about the surrounding environment surrounding the electronic apparatus 1, and user information and generate a sensing signal corresponding thereto. The main processor 5100 may control the driving or operation of the electronic apparatus 1 based on the sensing signal or perform data processing, functions, or operations related to the application installed on the electronic apparatus 1. The sensor unit 5400 may include at least one selected from a proximity sensor, an illumination sensor, an acceleration sensor, a magnetic sensor, a gravity sensor (G-sensor), a gyroscope sensor, a motion sensor, an RGB sensor, an infrared sensor (IR sensor), a finger scan sensor, an ultrasonic sensor, an optical sensor, a battery gauge, an environmental sensor (e.g., a barometer, a hygrometer, a thermometer, a radiation detection sensor, a heat detection sensor, or a gas detection sensor), and a chemical sensor (e.g., an electronic nose, a healthcare sensor, or a biometric recognition sensor).

The output unit 5500 may be for generating an output related to visual, auditory or tactile sensation and may include at least one selected from a display panel 10, an audio output unit 5510, a haptic module 5520, and a light output unit 5530.

The display panel 10 may display (output) information processed in the electronic apparatus 1. In an embodiment, for example, the display panel 10 may display execution screen information of an application driven in the electronic apparatus 1 or display user interface (UI) or graphical user interface (GUI) information corresponding to the execution screen information. The display panel 10 may include a display layer for displaying an image and a touch screen layer for detecting a user's touch input. Accordingly, the display panel 10 may function as one of input devices 5330 for providing an input interface between the electronic apparatus 1 and the user and may simultaneously function as one of output units 5500 for providing an output interface between the electronic apparatus 1 and the user.

The audio output unit 5510 may output audio data received from the wireless communicator 5200 or stored in the memory 5700, in a call signal reception mode, a call mode, a recording mode, a voice recognition mode, a broadcast reception mode, or the like. The audio output unit 5510 may also output an audio signal related to a function performed in the electronic apparatus 1 (e.g., a call signal reception sound or a message reception sound). The audio output unit 5510 may include a receiver and a speaker. At least one selected from the receiver and the speaker may be an audio generating device that is attached to the lower portion of the display panel 10 and vibrates the display panel 10 to output audio. The audio generating device may be a piezoelectric element or a piezoelectric actuator that contracts and expands according to an electric signal or may be an exciter that vibrates the display panel 10 by generating a magnetic force by using a voice coil.

The haptic module 5520 may generate various tactile effects that the user may feel. The haptic module 5520 may provide a vibration as a tactile effect to the user. The haptic module 5520 not only may transmit a tactile effect through direct contact but also may be implemented such that the user may feel a tactile effect through a muscle sense of the fingers, arms, or the like.

The light output unit 5530 may output a signal for notifying the occurrence of an event by using light of a light source. Examples of the event occurring in the electronic apparatus 1 may include message reception, call signal reception, missed call, alarm, schedule notification, email reception, and information reception through an application. The signal output from the light output unit 5530 may be implemented by the electronic apparatus 1 emitting light of a single color or a plurality of colors from the front surface or rear surface. The signal output may be terminated when the electronic apparatus 1 detects the user's identification of an event.

The interface unit 5600 may function as a path for various types of external devices connected to the electronic apparatus 1. The interface unit 5600 may include at least one of a wired/wireless headset port, an external charger port, a wired/wireless data port, a memory card port, a port for connecting a device including an identification module, an audio input/output (I/O) port, a video I/O port, and an earphone port. When an external device is connected to the interface unit 5600, the electronic apparatus 1 may perform suitable control related to the connected external device.

The memory 5700 may store data for supporting various functions of the electronic apparatus 1. The memory 5700 may store a plurality of applications (application programs) driven in the electronic apparatus 1, data for the operation of the electronic apparatus 1, and instructions. At least some of the plurality of applications may be downloaded from an external server through wireless communication. The memory 5700 may store an application for the operation of the main processor 5100 and may temporarily store input/output data such as a phonebook, a message, a still image, and a moving image. Also, the memory 5700 may store haptic data for various patterns of vibrations provided to the haptic module 5520 and audio data about various audios provided to the audio output unit 5510. The memory 5700 may include at least one type of storage medium from among flash memory type, hard disk type, solid state disk (SSD) type, silicon disk drive (SDD) type, multimedia card micro type, card type memory (e.g., SD and XD memories), random-access memory (RAM), static random-access memory (SRAM), read-only memory (ROM), electronically erasable programmable read-only memory (EEPROM), programmable read-only memory (PROM), magnetic memory, magnetic disk, and optical disk.

Under the control by the main processor 5100, the power supply unit 5800 may receive external power and/or internal power and supply the power to each of the components included in the electronic apparatus 1. The power supply unit 5800 may include a battery 80. Also, the power supply unit 5800 may include a connection port, and the connection port may be an example of the interface unit 5600 to which an external charger supplying power for charging the battery is electrically connected. Alternatively, the power supply unit 5800 may be configured to wirelessly charge the battery 80 without using the connection port. The battery 80 may be arranged not to overlap the main circuit board 50 in the third direction (z direction). The battery 80 may overlap the battery hole BH of the bracket 60.

The lower cover 90 may be a type of housing which supports the display panel 10 and to which the display panel 10 is assembled and may form the exterior of the electronic apparatus 1. The lower cover 90 may be arranged under the main circuit board 50 and the battery 80. The lower cover 90 may be fastened and fixed to the bracket 60. The lower cover 90 may include plastic, metal, or both plastic and metal.

A second camera hole CMH2 may be defined or formed in the lower cover 90 to expose the lower surface of the camera device 5310. The position of the camera device 5310 and the positions of the first and second camera holes CMH1 and CMH2 corresponding to the camera device 5310 are not limited to those illustrated in FIG. 2 and may be variously modified.

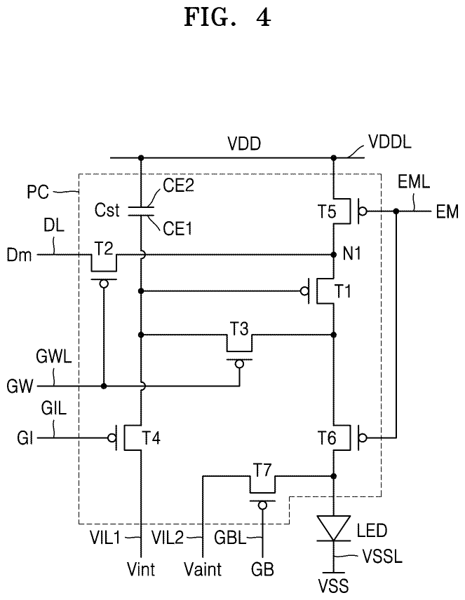

FIG. 4 is an equivalent circuit diagram schematically illustrating a light emitting diode of a display panel and a circuit connected to the light emitting diode according to an embodiment.

The display panel 10 described above with reference to FIG. 2 may provide an image through the pixels PX two-dimensionally arranged in the display area DA. Each pixel PX (see FIG. 2) may include a light emitting diode LED (see FIG. 4). In an embodiment where the display panel 10 of FIG. 2 includes pixels PX two-dimensionally arranged in the display area DA, the display area DA includes light emitting diodes LED (see FIG. 4) that are two-dimensionally arranged. The light emitting diode LED may be electrically connected to a pixel circuit PC. Like the light emitting diode LED, the pixel circuit PC may be arranged in the display area DA (see FIG. 2).

In an embodiment, the pixel circuit PC may include a first transistor T1, a second transistor T2, a third transistor T3, a fourth transistor T4, a fifth transistor T5, a sixth transistor T6, a seventh transistor T7, and a storage capacitor Cst. The first transistor T1 may be a driving transistor, and the second transistor T2, the third transistor T3, the fourth transistor T4, the fifth transistor T5, the sixth transistor T6, and the seventh transistor T7 may be switching transistors.

The first to seventh transistors T1, T2, T3, T4, T5, T6, and T7 may be p-channel metal-oxide-semiconductor field-effect transistor (MOSFET) (PMOS) or may be n-channel MOSFET (NMOS). In an embodiment, FIG. 4 illustrates that each of the first to seventh transistors T1, T2, T3, T4, T5, T6, and T7 is PMOS. The first to seventh transistors T1, T2, T3, T4, T5, T6, and T7 may be transistors including a low-temperature polycrystalline silicon (LTPS) semiconductor layer.

Although FIG. 4 illustrates an embodiment where each of the first to seventh transistors T1, T2, T3, T4, T5, T6, and T7 is PMOS, the disclosure is not limited thereto. In another embodiment, each of the first to seventh transistors T1, T2, T3, T4, T5, T6, and T7 may be NMOS. In an embodiment, at least one selected from the first to seventh transistors T1, T2, T3, T4, T5, T6, and T7 may be PMOS or may be NMOS. In an embodiment, for example, among the first to seventh transistors T1, T2, T3, T4, T5, T6, and T7, the third transistor T3 and the fourth transistor T4 may be NMOS and the others may be PMOS. In an embodiment, for example, among the first to seventh transistors T1, T2, T3, T4, T5, T6, and T7, the fifth transistor T5 may be PMOS and the others may be NMOS.

Although FIG. 4 illustrates an embodiment where the first to seventh transistors T1, T2, T3, T4, T5, T6, and T7 are transistors including an LTPS semiconductor layer, the disclosure is not limited thereto. In another embodiment, the first to seventh transistors T1, T2, T3, T4, T5, T6, and T7 may be transistors including an oxide semiconductor layer. In an embodiment, at least one selected from the first to seventh transistors T1, T2, T3, T4, T5, T6, and T7 may be a transistor including an LTPS semiconductor layer, and the others or the remaining thereof may be transistors including an oxide semiconductor layer. In an embodiment, the third transistor T3 and the fourth transistor T4 may include an oxide semiconductor layer with a low leakage current, and the first, second, fifth, sixth, and seventh transistors T1, T2, T5, T6, and T7 may include a semiconductor layer including polycrystalline silicon. In an embodiment, the fifth transistor T5 may include a semiconductor layer including polycrystalline silicon, and the first, second, third, fourth, sixth, and seventh transistors T1, T2, T3, T4, T6, and T7 may include an oxide semiconductor layer.

The pixel circuit PC may be electrically connected to signal lines and voltage lines. The signal lines may include a gate line such as a scan signal line GWL, a bypass control line GBL, an initialization control line GIL, and an emission control line EML, and a data line DL. The voltage lines may include first and second initialization voltage lines VIL1 and VIL2 and a first voltage line VDDL.

The first voltage line VDDL may be connected to transmit a first power voltage VDD to the first transistor T1. The first initialization voltage line VIL1 may be connected to transmit a first initialization voltage Vint for initializing the first transistor T1 to the pixel circuit PC. The second initialization voltage line VIL2 may be connected to transmit a second initialization voltage Vaint for initializing a first electrode of the light emitting diode LED to the pixel circuit PC.

The first transistor T1 may be electrically connected to the first voltage line VDDL via the fifth transistor T5 and may be electrically connected to the light emitting diode LED via the sixth transistor T6. The first transistor T1 may function as a driving transistor and may receive a data signal Dm based on a switching operation of the second transistor T2 to supply a driving current to the light emitting diode LED.

The second transistor T2 may be a data write transistor and may be electrically connected to the scan signal line GWL and the data line DL. The second transistor T2 may be electrically connected to the first voltage line VDDL via the fifth transistor T5. The second transistor T2 may perform a switching operation of transmitting the data signal Dm received through the data line DL to a first node N1 by being turned on according to a scan signal GW received through the scan signal line GWL.

The third transistor T3 may be electrically connected to the scan signal line GWL and may be electrically connected to the light emitting diode LED via the sixth transistor T6. According to the scan signal GW received through the scan signal line GWL, the third transistor T3 may be turned on to diode-connect the first transistor T1, i.e., to connect the first transistor T1 in a diode form.

The fourth transistor T4 may be a first initialization transistor and may be electrically connected to the initialization control line GIL and the first initialization voltage line VIL1. In response to an initialization control signal GI received through the initialization control line GIL, the fourth transistor T4 may be turned on to transmit the first initialization voltage Vint from the first initialization voltage line VIL1 to a gate electrode of the first transistor T1 to initialize a voltage of the gate electrode of the first transistor T1. The initialization control signal GI may correspond to a scan signal from another pixel circuit arranged in the previous row to the pixel circuit PC.

The fifth transistor T5 may be an operation control transistor, and the sixth transistor T6 may be an emission control transistor. The fifth transistor T5 and the sixth transistor T6 may be electrically connected to the emission control line EML and may be simultaneously turned on in response to an emission control signal EM received through the emission control line EL, to form a current path such that a driving current may flow from the first voltage line VDDL toward the light emitting diode LED. A first electrode of the light emitting diode LED may be electrically connected to the first transistor T1 through the sixth transistor T6, and a second electrode thereof may be electrically connected to a second voltage line VSSL configured to supply a second power voltage VSS.

The seventh transistor T7 may be a second initialization transistor and may be electrically connected to the bypass control line GBL, the second initialization voltage line VIL2, and the sixth transistor T6. In response to a bypass control signal GB received through the bypass control line GBL, the seventh transistor T7 may be turned on to transmit the second initialization voltage Vaint from the second initialization voltage line VIL2 to the first electrode of the light emitting diode LED to initialize the first electrode of the light emitting diode LED.

The storage capacitor Cst may include a first electrode CE1 and a second electrode CE2. The first electrode CE1 may be electrically connected to the gate electrode of the first transistor T1, and the second electrode CE2 may be electrically connected to the first voltage line VDDL. The storage capacitor Cst may be configured to store and maintain a voltage corresponding to the voltage difference between the first voltage line VDDL and the gate electrode of the first transistor T1 to maintain a voltage applied to the gate electrode of the first transistor T1.

Although FIG. 4 illustrates an embodiment where the first and second initialization voltage lines VIL1 and VIL2 are electrically connected to the fourth transistor T4 and the seventh transistor T7 respectively, the disclosure is not limited thereto. In another embodiment, the first and second initialization voltage lines VIL1 and VIL2 may be the same initialization voltage lines, and a single initialization voltage line may be electrically connected to each of the fourth transistor T4 and the seventh transistor T7.

Although FIG. 4 illustrates an embodiment where the pixel circuit PC includes seven transistors and one storage capacitor, the disclosure is not limited thereto. In another embodiment, the pixel circuit PC may include three to six transistors, may include eight or more transistors, or may include two or more capacitors.

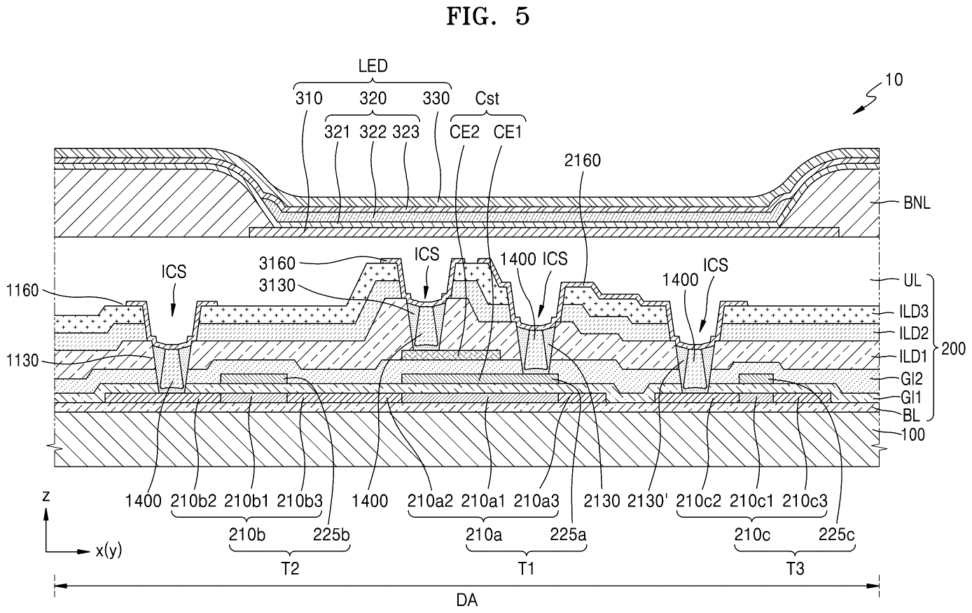

FIG. 5 is a cross-sectional view illustrating a portion of a display panel 10 according to an embodiment.

Referring to FIG. 5, an embodiment of the display panel 10 may include a substrate 100, a light emitting diode LED over the substrate 100, and a circuit layer 200 between the substrate 100 and the light emitting diode LED. The circuit layer 200 may include a pixel circuit electrically connected to the light emitting diode LED. The pixel circuit may include transistors and capacitors as described above with reference to FIG. 4, and FIG. 5 illustrates a portion of the circuit layer 200 including the storage capacitor Cst and the first to third transistors T1, T2, and T3 among the transistors described above with reference to FIG. 4.

The substrate 100 may include various materials such as a glass material or a plastic material such as polyethylen terephthalate (PET), polyethylen naphthalate (PEN), or polyimide. In an embodiment where the substrate 100 includes a plastic material, the flexibility may be improved compared to an embodiment where the substrate 100 includes a glass material. A buffer layer BL including silicon oxynitride, silicon oxide, and/or silicon nitride formed to prevent penetration of impurities may be provided over the substrate 100.

The first to third transistors T1, T2, and T3 may be arranged over the buffer layer BL. Each of the first to third transistors T1, T2, and T3 may include a semiconductor layer and a gate electrode. The first transistor T1 may include a first semiconductor layer 210a and a first gate electrode 225a, the second transistor T2 may include a second semiconductor layer 210b and a second gate electrode 225b, and the third transistor T3 may include a third semiconductor layer 210c and a third gate electrode 225c.

The first semiconductor layer 210a, the second semiconductor layer 210b, and the third semiconductor layer 210c may include amorphous silicon, polycrystalline silicon, an oxide semiconductor, or an organic semiconductor material. The first semiconductor layer 210a, the second semiconductor layer 210b, and the third semiconductor layer 210c may include a same material as each other or may include different materials from each other. In an embodiment, for example, the first semiconductor layer 210a, the second semiconductor layer 210b, and the third semiconductor layer 210c may include the same material such as amorphous silicon or polycrystalline silicon. In an embodiment, for example, the first semiconductor layer 210a, the second semiconductor layer 210b, and the third semiconductor layer 210c may include the same material such as an oxide semiconductor. In an embodiment, the first semiconductor layer 210a and the second semiconductor layer 210b may include polycrystalline silicon, and the third semiconductor layer 210c may include an oxide semiconductor.

Although FIG. 5 illustrates an embodiment where the first semiconductor layer 210a, the second semiconductor layer 210b, and the third semiconductor layer 210c are arranged in (or directly on) a same layer (e.g., the buffer layer BL), the disclosure is not limited thereto. In another embodiment, the third semiconductor layer 210c may be arranged in (or directly on) a different layer than the first semiconductor layer 210a and the second semiconductor layer 210b. A gate insulating layer may be arranged between the gate electrode and the semiconductor layer of each of the first to third transistors T1, T2, and T3. FIG. 5 illustrates an embodiment where a first gate insulating layer GI1 is arranged over the first semiconductor layer 210a, the second semiconductor layer 210b, and the third semiconductor layer 210c. The first gate insulating layer GI1 may include an inorganic insulating material or an organic insulating material. In an embodiment, the first gate insulating layer GI1 may include an inorganic insulating material such as silicon oxynitride, silicon oxide, or silicon nitride and may have a single-layer or multi-layer structure of the above material.

The first gate electrode 225a, the second gate electrode 225b, and the third gate electrode 225c may be respectively arranged over the first semiconductor layer 210a, the second semiconductor layer 210b, and the third semiconductor layer 210c with the first gate insulating layer GI1 therebetween.

The first gate electrode 225a may overlap a channel area 210a1 of the first semiconductor layer 210a, the second gate electrode 225b may overlap a channel area 210b1 of the second semiconductor layer 210b, and the third gate electrode 225c may overlap a channel area 210c1 of the third semiconductor layer 210c in a plan view or when viewed in the z direction. The first semiconductor layer 210 a may include areas 210a2 and 210a3 arranged on both opposing sides of the channel area 210a1, where one of the areas 210a2 and 210a3 may be a source area and the other thereof may be a drain area. The second semiconductor layer 210 b may include areas 210b2 and 210b3 arranged on both sides of the channel area 210b1, where one of the areas 210b2 and 210b3 may be a source area and the other thereof may be a drain area. The third semiconductor layer 210c may include areas 210c2 and 210c3 arranged on both sides of the channel area 210c1, where one of the areas 210c2 and 210c3 may be a source area and the other thereof may be a drain area.

Each of the first gate electrode 225a, the second gate electrode 225b, and the third gate electrode 225c may include at least one selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and may have a single-layer or multi-layer structure including the above material.

The storage capacitor Cst may include a first electrode CE1 and a second electrode CE2. In an embodiment, the storage capacitor Cst may overlap the first transistor T1 in a plan view. In an embodiment, for example, the first electrode CE1 of the storage capacitor Cst may be integrated with the first gate electrode 225a, i.e., integrally formed with the first gate electrode 225a as a single unitary indivisible part. In another embodiment, the first gate electrode 225a and the first electrode CE1 of the storage capacitor Cst may be separated as separate components.

Each of the first electrode CE1 and the second electrode CE2 may include at least one selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and may have a single-layer or multi-layer structure including the above material.

A second gate insulating layer GI2 may be arranged between the first electrode CE1 and the second electrode CE2. The second gate insulating layer GI2 may include an inorganic insulating material or an organic insulating material. In an embodiment, the second gate insulating layer GI2 may include an inorganic insulating material such as silicon oxynitride, silicon oxide, or silicon nitride and may have a single-layer or multi-layer structure of the above material.

Each of a first interlayer insulating layer ILD1, a second interlayer insulating layer ILD2, and a third interlayer insulating layer ILD3 may be arranged over the second gate insulating layer GI2. The first interlayer insulating layer ILD1 and the third interlayer insulating layer ILD3 may include an inorganic insulating material such as silicon oxynitride, silicon oxide, or silicon nitride or may include an organic insulating material. The second interlayer insulating layer ILD2 may include an inorganic insulating material such as silicon oxynitride, silicon oxide, or silicon nitride.

The semiconductor layer of the transistor, the gate electrode thereof, and/or the electrodes of the storage capacitor Cst may be electrically connected to a voltage line or a signal line for providing a preset voltage or signal or may be electrically connected to another transistor. For the electrical connection described above, the circuit layer 200 of the display panel 10 according to an embodiment may include an interconnect structure ICS.

In an embodiment, the interconnect structure ICS may be arranged over the second semiconductor layer 210b. A first conductor 1130 may be in a contact hole defined in at least one insulating layer over the second semiconductor layer 210b and may not extend onto the upper surface of the at least one insulating layer described above. In such an embodiment, as illustrated in FIG. 5, the first conductor 1130 may be in a contact hole defined or formed through the first gate insulating layer GI1, the second gate insulating layer GI2, and the first interlayer insulating layer ILD1. The first conductor 1130 may extend along the inner wall (side inner surfaces) and the bottom surface of the contact hole (i.e., a lower inner surface of layers defining the contact hole) described above and may not be over the upper surface of the first interlayer insulating layer ILD1.

The first conductor 1130 may include a side part arranged over (along or to cover) the inner wall defining the contact hole described above and a lower part contacting the upper surface of the second semiconductor layer 210b. The contact hole is not filled with the first conductor 1130. In the contact hole, an inorganic filler 1400 may be in a recess defined by the side part and lower part of the first conductor 1130. The inorganic filler 1400 may at least partially fill the recess.

A second conductor 1160 may contact the upper surface of the side part of the first conductor 1130 and the upper surface of the inorganic filler 1400, and thus, the second conductor 1160 may be electrically connected to the area 210b2 of the second semiconductor layer 210b through the first conductor 1130.

In an embodiment, the second conductor 1160 may be a portion of the data line DL (see FIG. 4). In another embodiment, the data line DL (see FIG. 4) and the second conductor 1160 may be separate components and may be electrically connected to the second conductor 1160 through another contact hole not illustrated in FIG. 5. In some embodiments, the second conductor 1160 may contact the upper surface of the first conductor 1130, for example, the upper surface of the side part of the first conductor 1130, through a contact hole defined or formed through the second and third interlayer insulating layers ILD2 and ILD3.

The contact of the second conductor 1160 and the first conductor 1130 (e.g., direct contact between the second conductor 1160 and the first conductor 1130) and the contact of the first conductor 1130 and the second semiconductor layer 210b (e.g., direct contact between the first conductor 1130 and the second semiconductor layer 210b) may be arranged in a direction perpendicular to the upper surface of the substrate 100. The contact of the second conductor 1160 and the first conductor 1130 and the contact of the first conductor 1130 and the second semiconductor layer 210b may overlap each other in a direction perpendicular to the upper surface of the substrate 100, i.e., a thickness direction of the substrate 100 or the z direction.

As a comparative example, in a case where the first conductor 1130 extends through the above contact hole onto the upper surface of the first interlayer insulating layer ILD1 and the second conductor 1160 contacts a portion of the first conductor 1130 extending onto the upper surface of the first interlayer insulating layer ILD1, the contact of the second conductor 1160 and the first conductor 1130 and the contact of the first conductor 1130 and the second semiconductor layer 210b may be laterally offset (e.g. laterally shifted) in the x direction (or y direction). Therefore, a large area may be desired for the contact of the second semiconductor layer 210b and the second conductor 1160 through the first conductor 1130 in the display area DA. According to the comparative example, the contact of the second conductor 1160 and the first conductor 1130 and the contact of the first conductor 1130 and the second semiconductor layer 210b may not overlap each other when viewed in a direction (e.g., z direction) perpendicular to the upper surface of the substrate 100. In this case, the area occupied by the contact for electrical connection of the second conductor 1160, the first conductor 1130, and the second semiconductor layer 210b in the display area DA may become relatively large, and it may be difficult to implement a high-resolution display panel 10 including a lot of contact structures.

According to an embodiment, as described above, because the contact of the second conductor 1160 and the first conductor 1130 and the contact of the first conductor 1130 and the second semiconductor layer 210b overlap each other in a direction perpendicular to the upper surface of the substrate 100, the area occupied by the contact in the display area DA may be minimized and thus the space utilization of the display area DA may be improved and a high-resolution (e.g., 1500 pixels per inch (ppi) or higher) display panel 10 may be effectively implemented.

As a comparative example, in a case where an organic filler including an organic insulating material may be provided in a recess according to the shape of the first conductor 1130, a conductor, for example, the second conductor 1160, arranged over the organic filler may be lifted by the gas emitted from the organic filler in a heat treatment process performed in the manufacturing process for the display panel 10, and in this case, the contact of the second conductor 1160 and the first conductor 1130 may be damaged or may not be effectively maintained. Also, in this case, an intermediate conductor may be desired to be arranged between the first conductor 1130 and the second conductor 1160 to protect the organic filler, the number of processes may increase. In embodiments of the disclosure, the above problem may be effectively prevented by including the inorganic filler 1400.

In an embodiment, an interconnect structure ICS may be provided for electrical connection of the transistors. In an embodiment, for example, an electrical connection structure of the first gate electrode 225a of the first transistor T1 and the third semiconductor layer 210c of the third transistor T3 may include an interconnect structure ICS. In an embodiment, the first gate electrode 225a of the first transistor T1 may be integrally formed with the first electrode CE1 of the storage capacitor Cst as a single unitary indivisible part, and in such an embodiment, an electrical connection structure of the first gate electrode 225a of the first transistor T1 and the third semiconductor layer 210c of the third transistor T3 may be referred to as an electrical connection structure of the first electrode CE1 of the storage capacitor Cst and the third semiconductor layer 210c of the third transistor T3.

A first conductor 2130 and an inorganic filler 1400 may be in a contact hole of at least one insulating layer (e.g., the second gate insulating layer GI2 and the first interlayer insulating layer ILD1) over the first gate electrode 225a. The first conductor 2130 and the inorganic filler 1400 may be only in the corresponding contact hole. A first conductor 2130′ and an inorganic filler 1400 may be in a contact hole of at least one insulating layer (e.g., the first gate insulating layer GI1, the second gate insulating layer GI2, and the first interlayer insulating layer ILD1) over the third semiconductor layer 210c. The first conductor 2130′ and the inorganic filler 1400 may be only in the corresponding contact hole.

A second conductor 2160 may directly contact the upper surface of the side part of each of the first conductors 2130 and 2130′. In an embodiment, the second and third interlayer insulating layers ILD2 and ILD3 may be provided with contact holes respectively overlapping the first conductors 2130 and 2130′. The second conductor 2160 may directly contact the upper surface of each of the first conductors 2130 and 2130′, for example, the upper surface of the side part of each of the first conductors 2130 and 2130′, through the contact holes of the second and third interlayer insulating layers ILD2 and ILD3.

In an embodiment, an interconnect structure ICS may be provided for electrical connection of the voltage line and the electrode of the storage capacitor Cst. In an embodiment, a first conductor 3130 and an inorganic filler 1400 may be in a contact hole of at least one insulating layer (e.g., the first interlayer insulating layer ILD1) over the second electrode CE2 of the storage capacitor Cst. The first conductor 3130 and the inorganic filler 1400 may be only in the corresponding contact hole and may not extend onto the upper surface of the insulating layer in which the corresponding contact hole is formed.

A second conductor 3160 may directly contact the upper surface of the first conductor 3130, for example, the upper surface of the side part of the first conductor 3130. In an embodiment, the second and third interlayer insulating layers ILD2 and ILD3 may be provided with a contact hole overlapping the first conductor 3130 and the inorganic filler 1400, and the second conductor 3160 may directly contact the upper surface of the side part of the first conductor 3130 through the above contact hole.

In an embodiment, the second conductor 3160 may be a portion of the first voltage line VDDL (see FIG. 4). In another embodiment, the first voltage line VDDL (see FIG. 4) and the second conductor 3160 may be separate components and the first voltage line VDDL(see FIG. 4) may be electrically connected to the second conductor 3160 through another contact hole not illustrated in FIG. 5.

Each of the first conductors 1130, 2130, 2130′, and 3130 and the second conductors 1160, 2160, and 3160 may include at least one selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and may have a single-layer or multi-layer structure including the above material.

An upper insulating layer UL may be arranged over the interconnect structure ICS. The upper insulating layer UL may include an organic insulating material. The light emitting diode LED may be arranged over the upper insulating layer UL. The light emitting diode LED may include a pixel electrode 310, an intermediate layer 320, and an opposite electrode 330. Although not illustrated in FIG. 5, the pixel electrode 310 may be electrically connected to a transistor, for example, the sixth transistor T6 (see FIG. 4) described above with reference to FIG. 4.

The pixel electrode 310 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. In another embodiment, the pixel electrode 310 may further include a conductive oxide layer over and/or under the reflective layer. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). In an embodiment, the pixel electrode 310 may have a three-layer structure of ITO layer/Ag layer/ITO layer.

The intermediate layer 320 may include an emission layer 322 and first and second functional layers 321 and 323 respectively arranged under and over the emission layer 322. The first functional layer 321 may include a hole injection layer (HIL) and/or a hole transport layer (HTL), and the second functional layer 323 may include an electron transport layer (ETL) and/or an electron injection layer (EIL). In an embodiment, the intermediate layer 320 may include a tandem structure including a plurality of stack structures of the first functional layer 321, the emission layer 322, and the second functional layer 323.

A bank layer BNL may be arranged over the pixel electrode 310. The bank layer BNL may be provided with an opening overlapping the pixel electrode 310 and may cover the edge of the pixel electrode 310. The bank layer BNL may include an organic insulating material.

The opposite electrode 330 may include a conductive material having a low work function. In an embodiment, for example, the opposite electrode 330 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the opposite electrode 330 may further include a layer such as ITO, IZO, ZnO, or In₂O₃ over the (semi)transparent layer including the above material. The opposite electrode 330 may be integrally formed as a single unitary indivisible part in a plurality of light emitting diodes LED to correspond to a plurality of pixel electrodes 310.

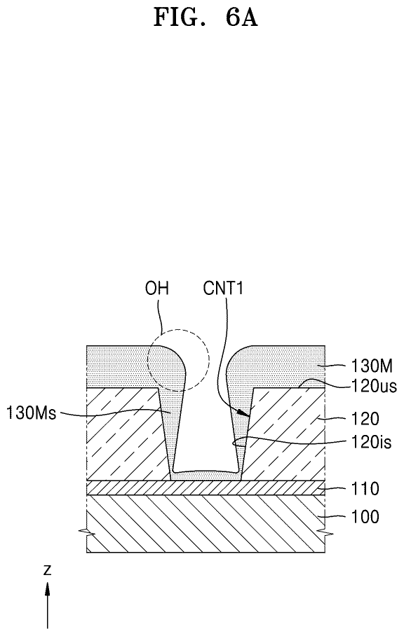

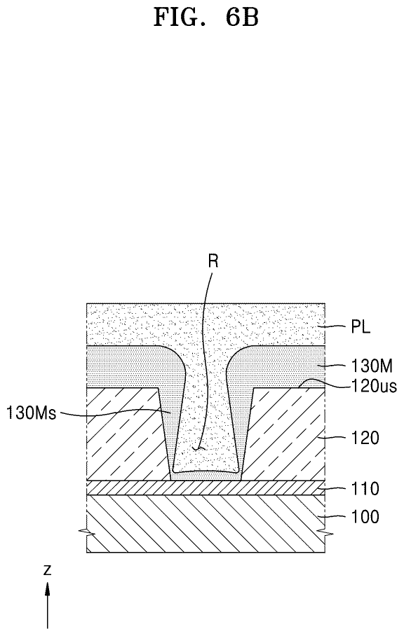

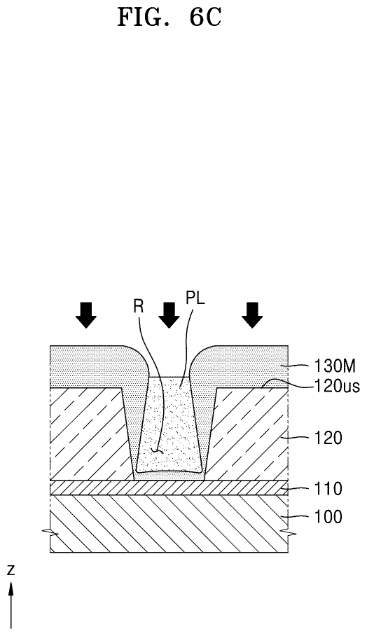

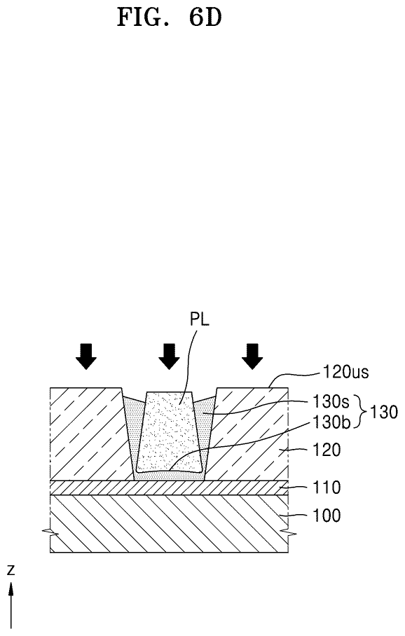

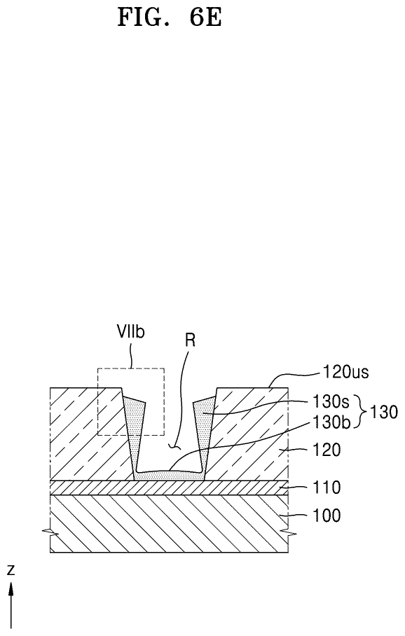

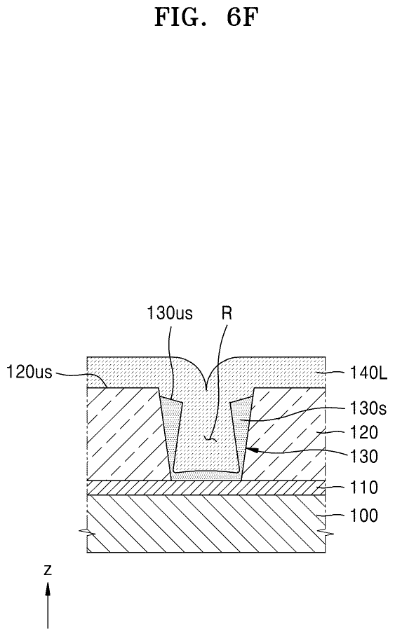

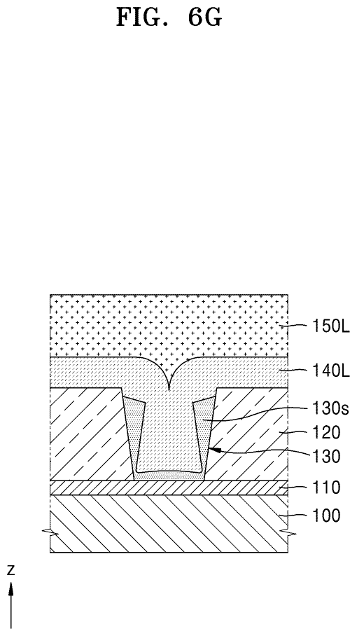

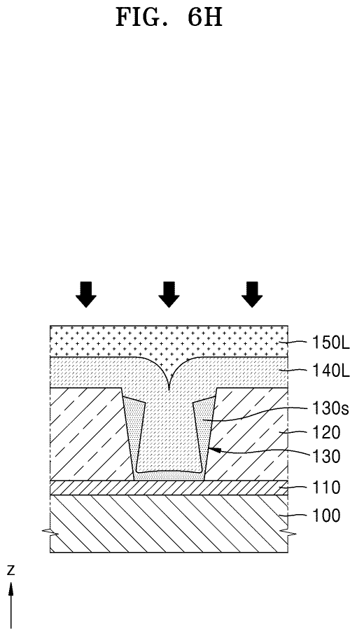

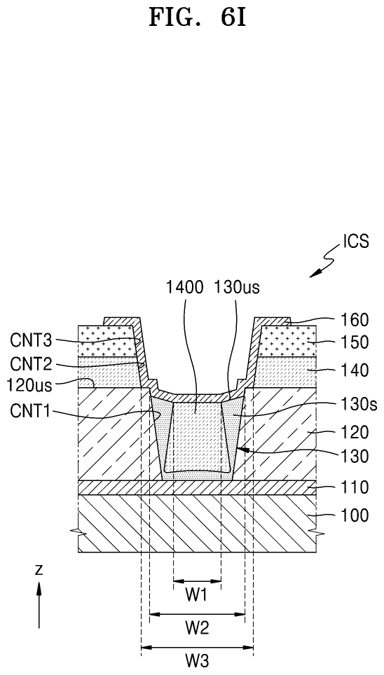

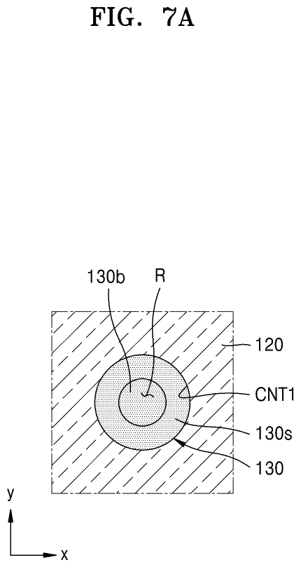

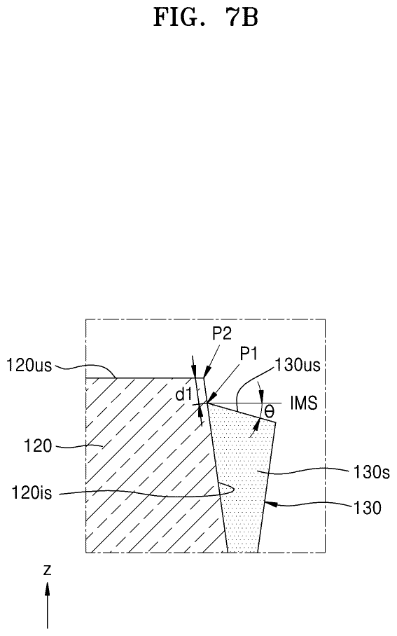

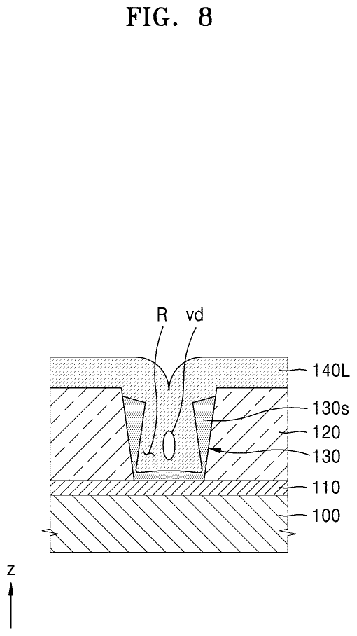

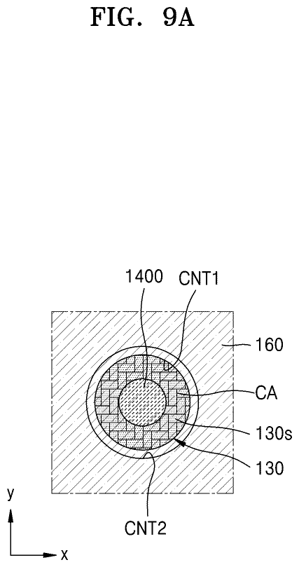

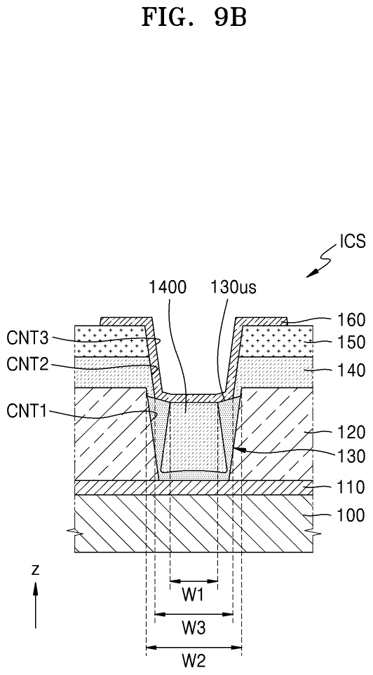

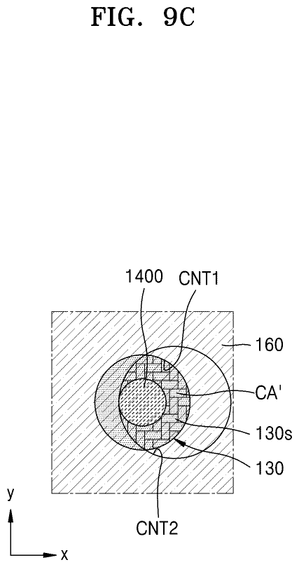

FIGS. 6A to 6I are cross-sectional views illustrating a process (or a method) of forming an interconnect structure ICS included in a circuit layer 200 (see FIG. 5) of a display panel 10 (see FIG. 5) according to an embodiment. FIG. 7A is a plan view of a first conductor 130 of FIG. 6E when viewed in a direction perpendicular to an upper surface of a substrate 100, FIG. 7B is an enlarged cross-sectional view of region VIIb of FIG. 6E, FIG. 8 is a cross-sectional view according to an embodiment of a process to be described with reference to FIG. 6F, FIG. 9A is a plan view illustrating a contact structure of a second conductor 160 and a first conductor 130 according to a process described with reference to FIG. 6I, FIG. 9B is a cross-sectional view of an interconnect structure ICS according to a process according to an embodiment, and FIG. 9C is a plan view illustrating a contact structure of a second conductor 160 and a first conductor 130 according to a process according to an embodiment.

Referring to FIGS. 6A to 6I, an embodiment of a process (or a method) of forming an interconnect structure ICS of a circuit layer 200 (see FIG. 5) may include a process of forming a first conductive material layer 110 over a substrate 100; a process of forming a first insulating layer 120 including a first contact hole CNT1 overlapping a portion of an upper surface of the first conductive material layer 110; a process of forming a first conductor 130 including a side part on an inner wall of the first insulating layer 120 defining the first contact hole CNT1 and a lower part integrally connected to the side part (or integrally formed with the side part as a single unitary indivisible part) and directly contacting a portion of the upper surface of the first conductive material layer 110, a process of forming an inorganic filler 1400 arranged in a recess R surrounded by the side part of the first conductor 130 in the first contact hole CNT1, and a process of forming a second conductor 160 directly contacting an upper surface of the side part of the first conductor 130.

Referring to FIG. 6A, a first conductive material layer 110 may be formed over a substrate 100. Although not illustrated in FIG. 6A, various insulating layers including a buffer layer BL (see FIG. 5) may be first formed over the substrate 100 before forming the first conductive material layer 110.

The first conductive material layer 110 may include a semiconductor material, a metal material, and/or the like. The first conductive material layer 110 may include polycrystalline silicon, an oxide semiconductor, or an organic semiconductor, or may include at least one selected from silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and may have a single-layer or multi-layer structure including the above material.

A first insulating layer 120 may be formed over the first conductive material layer 110. The first insulating layer 120 may be provided with a first contact hole CNT1 that exposes a portion of the upper surface of the first conductive material layer 110, that is, the first contact hole CNT1 may be formed through the first insulation layer 120 to expose the portion of the upper surface of the first conductive material layer 110. The first insulating layer 120 may include an inorganic insulating material including silicon oxynitride, silicon oxide, and/or silicon nitride or may include an organic insulating material. The first insulating layer 120 may have a single-layer or multi-layer structure including the above insulating material.

Thereafter, a first conductor 130 (see FIG. 6E) may be formed in the first contact hole CNT1 of the first insulating layer 120. A process of forming the first conductor 130 (see FIG. 6E) will be described with reference to FIGS. 6A to 6E.

As illustrated in FIG. 6A, a conductive layer 130M may be formed over the first insulating layer 120 including the first contact hole CNT1. The conductive layer 130M may include a metal material. The conductive layer 130M may include at least one selected from silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and may have a single-layer or multi-layer structure including the above material. In an embodiment, the conductive layer 130M may be formed through a sputtering process.

A conductive material (e.g., a metal material) for forming the conductive layer 130M may be deposited by progressing also into the first contact hole CNT1 with a preset depth. The conductive layer 130M may be continuously formed over a portion of the upper surface of the first conductive material layer 110 by passing through an upper surface 120us of the first insulating layer 120 and an inner wall 120is of the first insulating layer 120 defining the first contact hole CNT1. A conductive material (e.g., a metal material) forming the conductive layer 130M by the first contact hole CNT1 may form an overhang structure OH near a point, at which the inner wall 120is and the upper surface 120us of the first insulating layer 120 meet each other. Also, a portion 130Ms of the conductive layer 130M arranged over the inner wall 120 is of the first insulating layer 120 may have a shape in which the thickness thereof decreases gradually in the depth direction (e.g., −z direction) of the first contact hole CNT1.

Referring to FIG. 6B, a planarization layer PL may be formed over the conductive layer 130M. The planarization layer PL may include an organic insulating material or a photoresist. The planarization layer PL may cover the upper surface of the conductive layer 130M and may fill a recess R surrounded by the portion 130Ms of the conductive layer 130M.

Referring to FIG. 6C, a portion of the planarization layer PL may be removed through an etch back process. A portion of the planarization layer PL over the upper surface of the conductive layer 130M may be removed through an etch back process. Another portion of the planarization layer PL may remain in the recess R after the etch back process.

Referring to FIGS. 6C and 6D, a first conductor 130 may be formed by removing a portion of the conductive layer 130M through an etch back process. A portion of the conductive layer 130M arranged over the upper surface 120 us of the first insulating layer 120 may be removed, and in this case, the overhang structure OH (see FIG. 6A) described above with reference to FIG. 6A may also be removed. The conductive layer 130M left through the etch back process may form the first conductor 130. In order to form the first conductor 130, the planarization layer PL in the recess R may correspond to a type of protection layer or sacrificial layer for preventing etching of a portion of the conductive layer 130M corresponding to the first conductor 130. The first conductor 130 may include a side part 130s on the inner wall 120is of the first insulating layer 120 and a lower part 130b on a portion of the upper surface of the first conductive material layer 110.

Referring to FIGS. 6D and 6E, the planarization layer PL in the recess R may be removed. Thus, a first conductor 130 may be in the first contact hole CNT1, and a recess R may be formed inside the first conductor 130.

Referring to FIGS. 6E and 7A, the recess R may be surrounded by the side part 130s of the first conductor 130 in the plan view, and the bottom surface of the recess R (or a lower inner surface defining the recess R) may correspond to the lower part 130b of the first conductor 130.

Referring to FIGS. 6E and 7B, the side part 130s of the first conductor 130 may directly contact the inner wall 120is of the first insulating layer 120. A first point P1, at which the side part 130s of the first conductor 130 and the inner wall 120is of the first insulating layer 120 meet or contact each other, may be spaced apart by a first distance d1 along the inner wall 120is from a second point P2, at which the inner wall 120is of the first insulating layer 120 and the upper surface 120us of the first insulating layer 120 meet each other. In such an embodiment where the first point P1 is spaced apart from the second point P2 along the inner wall 120is of the first insulating layer 120, it may be possible to effectively prevent the material of the conductive layer 130M (see FIG. 6D) from remaining on the upper surface 120us of the first insulating layer 120.

An upper surface 130us of the side part 130s of the first conductor 130 may be located on substantially a same plane as an imaginary plane IMS parallel to the upper surface of the substrate 100 (see FIG. 6E). Alternatively, the upper surface 130us of the side part 130s of the first conductor 130 may be inclined at a first angle θ with respect to the imaginary plane IMS due to the shape of the overhang structure OH illustrated in FIG. 6A. The first angle θ may be greater than about 0 degrees and equal to or less than about 45 degrees (0°<θ≤45°). In such an embodiment where the upper surface 130us of the side part 130s of the first conductor 130 is at the first angle θ with respect to the imaginary plane IMS, the contact area with a second conductor 160 (see FIG. 6I) described below may be increased compared to a case where the upper surface 130us of the side part 130s of the first conductor 130 is substantially parallel to the imaginary plane IMS.

Thereafter, a process of forming an inorganic filler 1400 (see FIG. 6I) arranged in the recess R may be performed. The process of forming the inorganic filler 1140 (see FIG. 6I) will be described with reference to FIGS. 6F to 6I.

Referring to FIG. 6F, an insulating material layer 140L may be formed over the first insulating layer 120 with the first conductor 130 formed in the first contact hole CNT1. The insulating material layer 140L may include an inorganic insulating material such as silicon oxynitride, silicon nitride, and/or silicon oxide.

The insulating material layer 140L may be formed on the upper surface 120us of the first insulating layer 120 and in the recess R. In an embodiment, for example, the insulating material layer 140L may be arranged over the upper surface 120us of the first insulating layer 120 and the upper surface 130us of the side part 130s of the first conductor 130 and may at least partially fill the recess R. Although FIG. 6F illustrates an embodiment where the insulating material layer 140L entirely fills the recess R, the disclosure is not limited thereto. In another embodiment, as illustrated in FIG. 8, the insulating material layer 140L may partially fill the recess R, and a void vd may exist (or be formed) therein. Hereinafter, for convenience of description, the structure illustrated in FIG. 6F will be described as an example.

Referring to FIG. 6G, an additional insulating material layer 150L may be formed over the insulating material layer 140L. The additional insulating material layer 150L may entirely cover the upper surface of the insulating material layer 140L. The additional insulating material layer 150L may include an organic insulating material or an inorganic insulating material.

Referring to FIG. 6H, by performing an etch back process on the entire surface of the additional insulating material layer 150L, the thickness of the additional insulating material layer 150L may be adjusted and the flatness of the upper surface of the additional insulating material layer 150L may be adjusted.

Referring to FIG. 6I, a portion of the insulating material layer 140L and the additional insulating material layer 150L corresponding to the first contact hole CNT1 may be removed by using a process such as etching.

In the process of removing a portion of the insulating material layer 140L corresponding to the first contact hole CNT1, a portion of the insulating material layer 140L present in the recess R may be an inorganic filler 1400, and another portion of the insulating material layer 140L arranged over the first insulating layer 120 may be a second insulating layer 140 including a second contact hole CNT2. The second insulating layer 140 may be separated from the inorganic filler 1400, and the inorganic filler 1400 and the second insulating layer 140 may include the same inorganic insulating material.

In the process of removing a portion of the insulating material layer 140L described above, the first conductor 130 may be exposed to the outside through the second contact hole CNT2.

In the process of removing a portion of the additional insulating material layer 150L corresponding to the first contact hole CNT1, a third insulating layer 150 including a third contact hole CNT3 may be formed. The third insulating layer over the second insulating layer may have the third contact hole CNT3. The third contact hole CNT3 may overlap the second contact hole CNT2. The third contact hole CNT3 and the second contact hole CNT2 may be formed through a same etching process and may be considered as one contact hole.

Thereafter, a second conductor 160 may be formed. After forming the inorganic filler 1400, the second insulating layer 140, and the third insulating layer 150, a conductive layer (not illustrated) may be formed and then patterned to form the second conductor 160. The second conductor 160 may include at least one selected from silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and may have a single-layer or multi-layer structure including the above material.

The second conductor 160 may directly contact the upper surface of the first conductor 130, for example, the upper surface 130us of the side part 130s of the first conductor 130. The second conductor 160 may also directly contact the upper surface of the inorganic filler 1400. The second conductor 160 may directly contact the first conductor 130 and the inorganic filler 1400 through the second and third contact holes CNT2 and CNT3.

In an embodiment, the second contact hole CNT2 may entirely expose the upper surface of the inorganic filler 1400 and the upper surface 130us of the first conductor 130 as illustrated in FIG. 6I. In an embodiment, for example, a third width W3 of the lower portion of the second contact hole CNT2 measured by using a point, at which the lower portion of the inner wall of the second insulating layer 140 defining the second contact hole CNT2 and the upper surface 120us of the first insulating layer 120 meet each other, may be greater than a second width W2 of the upper portion of the first contact hole CNT1 measured by using a point, at which the inner wall and the upper surface 120us of the first insulating layer 120 meet each other, and the second width W2 of the first contact hole CNT1 described above may be greater than a first width W1 of the upper surface of the inorganic filler 1400. The upper surface 130us of the side part 130s of the first conductor 130 may entirely contact the second conductor 160. In the plan view (or when viewed in a direction perpendicular to the upper surface of the substrate 100), as illustrated in FIG. 9A, a contact area CA of the second conductor 160 and the first conductor 130 may have a closed-loop shape (e.g., a ring shape).

In another embodiment, as illustrated in FIG. 9B, the third width W3 may be greater than the first width W1 and less than the second width W2. In such an embodiment, the lower portion of the inner wall of the second insulating layer 140 may extend to the upper surface 130us of the side part 130s of the first conductor 130, and the third width W3 of the lower portion of the second contact hole CNT2 measured by using a point, at which the inner wall of the second insulating layer 140 and the upper surface 130us of the side part 130s of the first conductor 130 meet each other, may be greater than the first width W1 and less than the second width W2. In such an embodiment, as illustrated in FIG. 9B, a portion of the upper surface 130us of the side part 130s of the first conductor 130 may contact the second conductor 160, and in the plan view (or when viewed in a direction perpendicular to the upper surface of the substrate 100), the contact area CA of the second conductor 160 and the first conductor 130 may have a closed-loop shape (e.g., a ring shape).

In another embodiment, as illustrated in FIG. 9C, where the center of the second contact hole CNT2 is spaced apart from the center of the first contact hole CNT1 (e.g., when the center of the second contact hole CNT2 is offset from the center of the first contact hole CNT1), a contact area CA′ of the second conductor 160 and the first conductor 130 may have a substantially arc shape.

The area of the contact area (CA of FIG. 9A or CA′ of FIG. 9C) of the second conductor 160 and the first conductor 130 may be in a range of about 0.039 square micrometer (μm²) to about 3.11 μm².

The interconnect structure ICS of the first conductive material layer 110, the first conductor 130, and the second conductor 160 described with reference to FIGS. 6A to 6I may be provided in the circuit layer 200 (see FIG. 5) described above with reference to FIG. 5. The first conductive material layer 110 may be the semiconductor layer or the electrode described above with reference to FIG. 5. In an embodiment, the first conductive material layer 110 may be the second semiconductor layer 210b (see FIG. 5) or the third semiconductor layer 210c (see FIG. 5). In an embodiment, the first conductive material layer 110 may be the first gate electrode 225a (see FIG. 5), the first electrode CE1 (see FIG. 5) of the storage capacitor Cst, or the second electrode CE2 (see FIG. 5) of the storage capacitor Cst.

In an embodiment, the first conductive material layer 110, the first conductor 130, and the second conductor 160 described with reference to FIGS. 6A to 6I, 7A, 7B, 8, and 9A to 9C may respectively correspond to the second semiconductor layer 210b of the second transistor T2 of FIG. 5, the first conductor 1130, and the second conductor 1160.

In an embodiment, the first conductive material layer 110, the first conductor 130, and the second conductor 160 described with reference to FIGS. 6A to 6I, 7A, 7B, 8, and 9A to 9C may respectively correspond to the first gate electrode 225a of the first transistor T1 of FIG. 5, the first conductor 2130, and the second conductor 2160. Also, the first conductive material layer 110, the first conductor 130, and the second conductor 160 described with reference to FIGS. 6A to 6I may respectively correspond to the third semiconductor layer 210c of the third transistor T3 of FIG. 5, the first conductor 2130, and the second conductor 2160.

In an embodiment, the first conductive material layer 110, the first conductor 130, and the second conductor 160 described with reference to FIGS. 6A to 6I, 7A, 7B, 8, and 9A to 9C may respectively correspond to the second electrode CE2 of the storage capacitor Cst of FIG. 5, the first conductor 3130, and the second conductor 3160.

According to an embodiment described with reference to FIGS. 6A to 6I, the additional insulating material layer 150L may be formed as described with reference to FIG. 6G and thus the third insulating layer 150 is formed as illustrated in FIG. 6I; however, the disclosure is not limited thereto. In another embodiment, the additional insulating material layer 150L may not be formed, and thus, the etch back process (FIG. 6H) for removing a portion of the additional insulating material layer 150L may also be omitted. In another embodiment, the additional insulating material layer 150L may be formed, but the etch back process (FIG. 6H) for removing a portion of the additional insulating material layer 150L may be omitted. That is, the process described with reference to FIG. 6G and/or FIG. 6H may be optional.

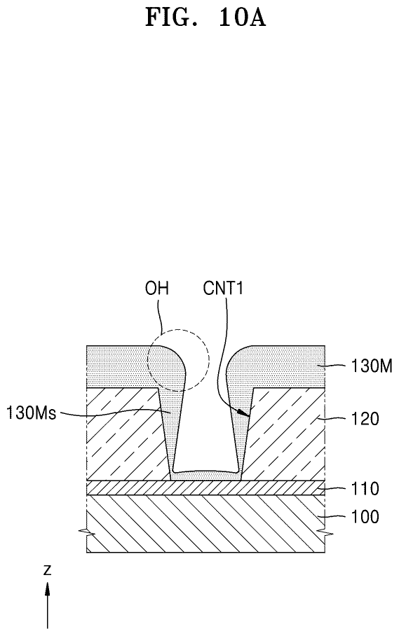

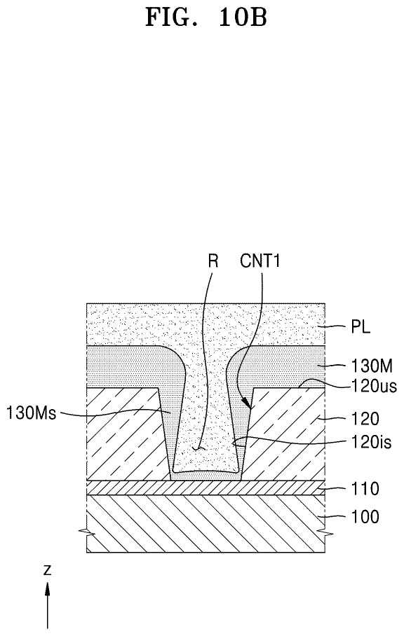

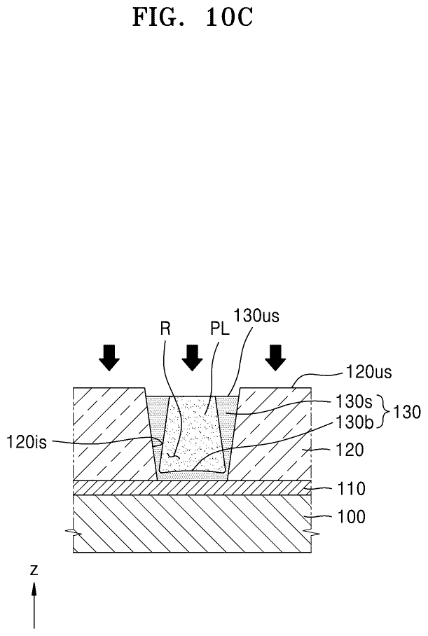

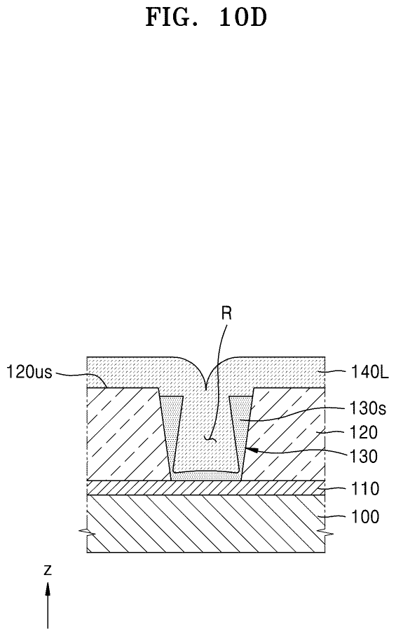

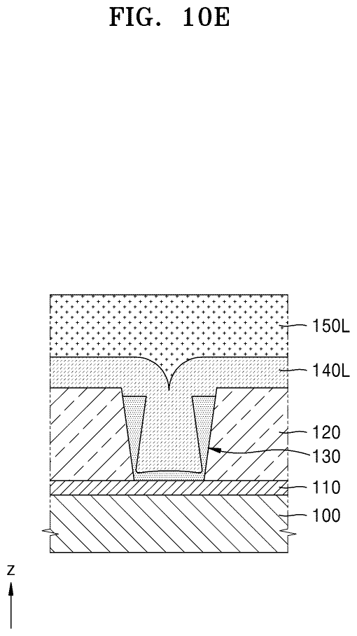

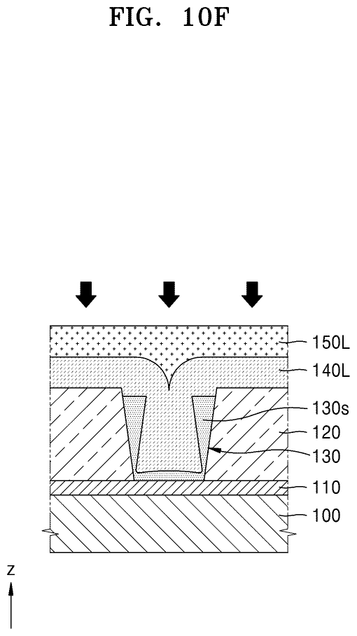

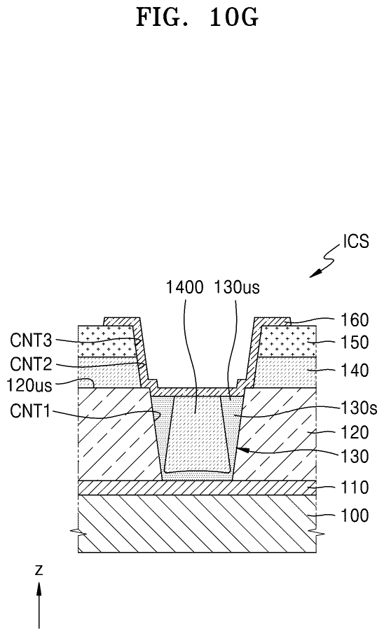

FIGS. 10A to 10G are cross-sectional views illustrating a process of forming an interconnect structure ICS included in a circuit layer 200 (see FIG. 5) of a display panel 10 (see FIG. 5) according to an embodiment.

Referring to FIG. 10A, as those described above with reference to FIG. 6A, a first conductive material layer 110 may be formed over a substrate 100, and a first insulating layer 120 including a first contact hole CNT1 may be formed. Then, a conductive layer 130M may be formed over the first insulating layer 120 including the first contact hole CNT1. The material and particular process for the conductive layer 130M are the same as those described above with reference to FIG. 6A.

Referring to FIG. 10B, a planarization layer PL may be formed over the conductive layer 130M. The planarization layer PL may include an organic insulating material or a photoresist. The planarization layer PL may cover the upper surface of the conductive layer 130M and may fill a recess R surrounded by a portion 130Ms of the conductive layer 130M arranged on an inner wall 120is of the first insulating layer 120 defining the first contact hole CNT1.

Referring to FIG. 10C, a portion of the planarization layer PL and a portion of the conductive layer 130M may be removed through an etch back process. A process of removing a portion of the planarization layer PL and a portion of the conductive layer 130M may be performed in a same etching process. The etching process may be performed by using an etching gas having an etch selectivity of about 1 of the conductive layer 130M with respect to the planarization layer PL.

As a portion of the conductive layer 130M is removed, a first conductor 130 may be formed in the first contact hole CNT1, and a portion of the planarization layer PL may remain in the recess R.

The first conductor 130 may include a side part 130s arranged on the inner wall 120ᵢₛ of the first insulating layer 120 and a lower part 130b integrally connected to the side part 130s (or integrally formed with the side part 130s as a single unitary indivisible part) and contacting a portion of the upper surface of the first conductive material layer 110. The side part 130s of the first conductor 130 may directly contact the inner wall 120ᵢₛ of the first insulating layer 120. The side part 130s of the first conductor 130 may have a shape in which its thickness decreases gradually in a direction (e.g., −z direction) toward the lower part 130b. As described above with reference to FIG. 7B, a point, at which the side part 130s of the first conductor 130 and the inner wall 120ᵢₛ of the first insulating layer 120 meet each other, may be located under a point, at which the upper surface 120ᵤₛ and the inner wall 120ᵢₛ of the first insulating layer 120 meet each other. The upper surface 130ᵤₛ of the side part 130s of the first conductor 130 may be substantially flat with (e.g., parallel to) the upper surface of the substrate 100.

Thereafter, the planarization layer PL remaining in the recess R may be removed.

A process to be described with reference to FIGS. 10D to 10G may be the same as the process described above with reference to FIGS. 6F to 6I.

Referring to FIG. 10D, an insulating material layer 140L may be formed over the first insulating layer 120 where the first conductor 130 has been formed. The insulating material layer 140L may include an inorganic insulating material such as silicon oxynitride, silicon nitride, and/or silicon oxide.

The insulating material layer 140L may be formed on the upper surface 120ᵤₛ of the first insulating layer 120 and in the recess R. In an embodiment, for example, the insulating material layer 140L may be arranged over the upper surface 120ᵤₛ of the first insulating layer 120 and the upper surface 130ᵤₛ of the side part 130s of the first conductor 130 and may at least partially fill the recess R. Although FIG. 10D illustrates an embodiment where the insulating material layer 140L entirely fills the recess R, the disclosure is not limited thereto. In another embodiment, as described above with reference to FIG. 8, the insulating material layer 140L may partially fill the recess R, and a void vd (see FIG. 8) may exist or be formed therein.

Referring to FIG. 10E, an additional insulating material layer 150L may be formed over the insulating material layer 140L. The additional insulating material layer 150L may entirely cover the upper surface of the insulating material layer 140L. The additional insulating material layer 150L may include an organic insulating material or an inorganic insulating material.

Referring to FIG. 10F, by performing an etch back process on the entire surface of the additional insulating material layer 150L, the thickness of the additional insulating material layer 150L may be adjusted and the flatness of the upper surface of the additional insulating material layer 150L may be adjusted.

Referring to FIG. 10G, a portion of the insulating material layer 140L and the additional insulating material layer 150L corresponding to the first contact hole CNT1 may be removed by using a process such as etching.

In the process of removing a portion of the insulating material layer 140L corresponding to the first contact hole CNT1, a portion of the insulating material layer 140L present in the recess R may be an inorganic filler 1400, and another portion of the insulating material layer 140L arranged over the first insulating layer 120 may be a second insulating layer 140 including a second contact hole CNT2. The second insulating layer 140 may be separated from the inorganic filler 1400, and the inorganic filler 1400 and the second insulating layer 140 may include the same inorganic insulating material. In the process of removing a portion of the insulating material layer 140L described above, the first conductor 130 may be exposed to the outside through the second contact hole CNT2.

In the process of removing a portion of the additional insulating material layer 150L corresponding to the first contact hole CNT1, a third insulating layer 150 including a third contact hole CNT3 may be formed. The third contact hole CNT3 and the second contact hole CNT2 may be formed through a same etching process and may be considered as one contact hole.

Thereafter, a second conductor 160 may be formed. After forming the inorganic filler 1400, the second insulating layer 140, and the third insulating layer 150, a conductive layer (not illustrated) may be formed and then patterned to form the second conductor 160. The second conductor 160 may directly contact the upper surface of the first conductor 130, for example, the upper surface 130ᵤₛ of the side part 130s of the first conductor 130. The second conductor 160 may also directly contact the upper surface of the inorganic filler 1400. The second conductor 160 may directly contact the first conductor 130 and the inorganic filler 1400 through the second and third contact holes CNT2 and CNT3.

According to an embodiment described with reference to FIGS. 10A to 10G, the additional insulating material layer 150L may be formed as described with reference to FIG. 10E and thus the third insulating layer 150 is formed as illustrated in FIG. 10G; however, the disclosure is not limited thereto. In another embodiment, the additional insulating material layer 150L may not be formed, and thus, the etch back process (FIG. 10F) for removing a portion of the additional insulating material layer 150L may also be omitted. In another embodiment, the additional insulating material layer 150L may be formed, but the etch back process (FIG. 10F) for removing a portion of the additional insulating material layer 150L may be omitted. That is, the process described with reference to FIG. 10E and/or FIG. 10F may be optional.

The interconnect structure ICS of the first conductive material layer 110, the first conductor 130, and the second conductor 160 described with reference to FIGS. 10A to 10G may be provided in the circuit layer 200 (see FIG. 5) described above with reference to FIG. 5.

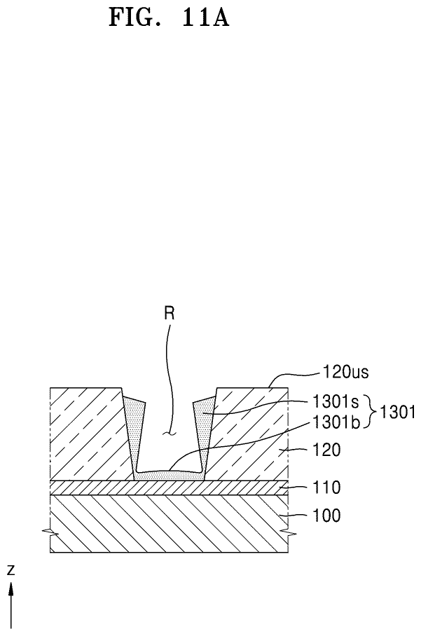

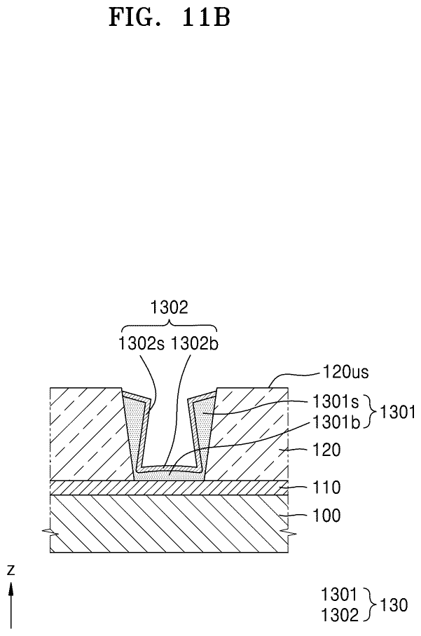

FIGS. 11A and 11B are cross-sectional views illustrating a process of forming a first conductor in a process of forming an interconnect structure included in a circuit layer of a display panel according to an embodiment.

FIG. 11A illustrates a first first conductor (hereinafter, will be referred to as “first-1 conductor”) 1301 formed in the first contact hole CNT1 of the first insulating layer 120 after the first insulating layer 120 is formed over the substrate 100. A process of forming the first-1 conductor 1301 may be the same as the process of forming the first conductor 130 (see FIG. 6E) described above with reference to FIGS. 6A to 6E.

The first-1 conductor 1301 may include a first side part 1301s arranged on (or directly contacting) the inner wall 120is of the first insulating layer 120 and a first lower part 1301b integrally formed with the first side part as a single unitary indivisible part and directly contacting a portion of the upper surface of the first conductive material layer 110. The recess R may be surrounded by the first side part 1301s of the first-1 conductor 1301.

In a state where the first-1 conductor 1301 is formed as illustrated in FIG. 11A, the process according to FIGS. 6A to 6E may be performed once again to form a second first conductor (hereinafter, will be referred to as “first-2 conductor”) 1302 as illustrated in FIG. 11B. The first-2 conductor 1302 may include a second side part 1302s arranged on (or directly contacting) the first side part 1301s of the first-1 conductor 1301 and a second lower part 1302b arranged on (or directly contacting) the first lower part 1301b of the first-1 conductor 1301. In an embodiment, the inorganic filler 1400 may be surrounded by the second side part 1302s of the second first conductor 1302.

By repeatedly performing the process described with reference to FIGS. 6A to 6E, the first conductor 130 may have a double structure of the first-1 conductor 1301 and the first-2 conductor 1302. By forming the first conductor 130 with a double structure, the contact area with the second conductor 160 (see FIG. 6I) may be increased.

Although FIGS. 11A and 11B illustrate an embodiment where some of the processes described with reference to FIGS. 6A to 6I, for example, the processes described with reference to FIGS. 6A to 6E, are repeatedly performed, the disclosure is not limited thereto. In another embodiment, the processes described with reference to FIGS. 10A to 10C among the processes described with reference to FIGS. 10A to 10G may be repeatedly performed to form the first conductor 130 as illustrated in FIG. 11B.

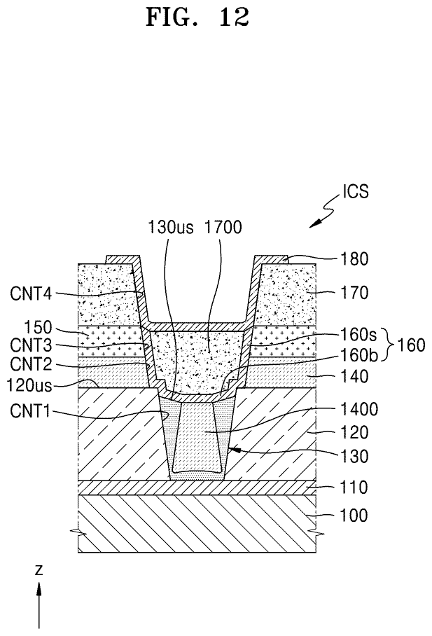

FIG. 12 is a cross-sectional view illustrating an interconnect structure ICS according to an embodiment.

Referring to FIG. 12, in an embodiment, a first insulating layer 120 may be arranged over a first conductive material layer 110, and a first conductor 130 and an inorganic filler 1400 may be arranged in a first contact hole CNT1 of the first insulating layer 120. The processes, materials, and other structural characteristics of the first conductive material layer 110, the first insulating layer 120, the first conductor 130, and the inorganic filler 1400 may be the same as those described above.

A second conductor 160 illustrated in FIG. 12 may be formed through a same process as the process of forming the first conductor 130. In an embodiment, for example, the second conductor 160 may be formed according to the process described with reference to FIGS. 6A to 6E or the process described with reference to FIGS. 10A to 10C. Thus, as illustrated in FIG. 12, similarly to the first conductor 130, the second conductor 160 may not extend onto the upper surfaces of the second and third insulating layers 140 and 150 but may be located only in the second and third contact holes CNT2 and CNT3 of the second and third insulating layers 140 and 150. In an embodiment where the process of forming the third insulating layer 150 is omitted as described above, the second conductor 160 may not extend onto the upper surface of the second insulating layer 140 but may be located only in the second contact hole CNT2 of the second insulating layer 140.

The second conductor 160 may include a side part 160s contacting the inner wall of the contact hole (e.g., the second and third contact holes CNT2 and CNT3) of the second and third insulating layers 140 and 150 and a lower part 160b contacting the first conductor 130. The lower part 160b of the second conductor 160 may contact the upper surface of each of the first conductor 130 and the inorganic filler 1400.

The second conductor 160 may not extend to the upper surface of the insulating layer corresponding to the contact hole in which the second conductor 160 is located. In an embodiment, for example, as illustrated in FIG. 12, where the second conductor 160 is in the second and third contact holes CNT2 and CNT3 of the second and third insulating layers 140 and 150, the second conductor 160 may not extend onto the upper surface of the third insulating layer 150. In another embodiment, the third insulating layer 150 may be omitted, and in such an embodiment, the second conductor 160 may be arranged together with an inorganic filler (hereinafter referred to as an upper inorganic filler 1700 in distinction from the inorganic filler 1400) in the second contact hole CNT2 that is a contact hole of the second insulating layer 140.

The upper inorganic filler 1700 may be formed through a same process as the process of FIGS. 6F to 6I or FIGS. 6F and 6I. The upper inorganic filler 1700 may include a same material as a fourth insulating layer 170. The upper inorganic filler 1700 and the fourth insulating layer 170 may include an inorganic insulating material such as silicon oxynitride, silicon nitride, and/or silicon oxide.

A third conductor 180 may contact the upper surface of each of the second conductor 160 and the upper inorganic filler 1700. The third conductor 180 may be formed after a contact hole (e.g., a fourth contact hole CNT4) of the fourth insulating layer 170 is formed, and the third conductor 180 may include at least one selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and may have a single-layer or multi-layer structure including the above material.

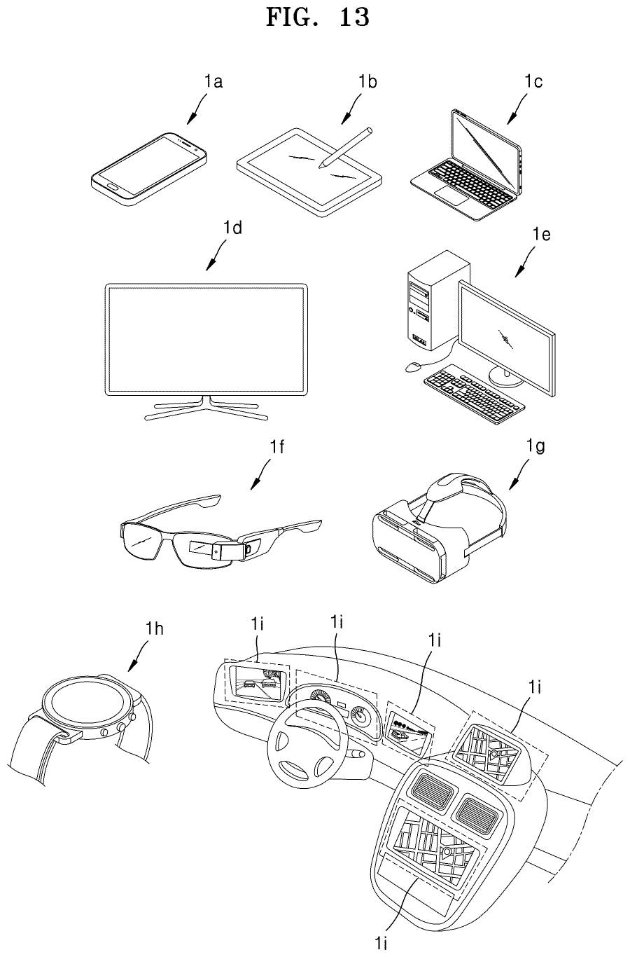

FIG. 13 is a perspective view illustrating an electronic apparatus including the display panel according to an embodiment.

Referring to FIG. 13, an embodiment of an electronic apparatus including the display panel according to the above embodiment may include not only an electronic device for displaying images, such as a smart phone (or a mobile phone) 1a, a tablet personal computer (PC) 1b, a laptop computer 1c, a television (TV) 1d, or a desk monitor 1e, but also a wearable electronic device including a display module, such as smart glasses 1f, a head-mounted display 1g, or a smart watch 1h, and a vehicle electronic device 1i including a display module, such as a center information display (CID) or a room mirror display arranged in the navigation, instrument panel, center fascia, or dashboard of a car.

According to embodiments of the disclosure, a manufacturing method capable of providing a high-resolution display panel by minimizing the area for contact while simplifying a manufacturing process, a display panel, and an electronic apparatus may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display panel comprising:
a substrate;
a light emitting diode arranged over the substrate; and
a circuit layer arranged between the substrate and the light emitting diode,
wherein the circuit layer comprises an interconnect structure,
wherein the interconnect structure comprises:
a first conductive material layer arranged over the substrate;
a first insulating layer arranged over the first conductive material layer, wherein a first contact hole is defined in the first insulating layer to overlap a portion of an upper surface of the first conductive material layer;
a first conductor comprising a side part and a lower part, wherein the side part is on an inner wall of the first insulating layer defining the first contact hole, and the lower part is integrally formed with the side part as a single unitary indivisible part and directly contacts a portion of the upper surface of the first conductive material layer;
an inorganic filler arranged in a recess surrounded by the side part of the first conductor in the first contact hole, wherein the inorganic filler comprises an inorganic insulating material;
a second insulating layer arranged over the first insulating layer, wherein a second contact hole is defined in the second insulating layer to overlap the first contact hole; and
a second conductor directly contacting an upper surface of the side part of the first conductor through the second contact hole of the second insulating layer.

2. The display panel of claim 1, wherein
the second insulating layer comprises an inorganic insulating material, and
the inorganic insulating material of the second insulating layer is the same as the inorganic insulating material of the inorganic filler.

3. The display panel of claim 1, wherein the side part of the first conductor is in direct contact with the inner wall of the first insulating layer, and
a first point, at which the side part of the first conductor and the inner wall of the first insulating layer contact each other, is spaced apart by a first distance along the inner wall from a second point, at which the inner wall of the first insulating layer and an upper surface of the first insulating layer meet each other.

4. The display panel of claim 1, wherein the upper surface of the side part of the first conductor is located on an imaginary plane parallel to an upper surface of the substrate.

5. The display panel of claim 1, wherein the upper surface of the side part of the first conductor is inclined with respect to an imaginary plane parallel to an upper surface of the substrate.

6. The display panel of claim 1, wherein the second conductor is in direct contact with an upper surface of the inorganic filler.

7. The display panel of claim 1, further comprising:
a third insulating layer over the second insulating layer,
wherein a third contact hole is defined in the third insulating layer and overlaps the second contact hole.

8. The display panel of claim 1, wherein the first conductor comprises:
a first first conductor comprising a first side part and a first lower part, wherein the first side part directly contacts an inner wall of the first insulating layer defining the first contact hole, and the first lower part is integrally formed with the first side part as a single unitary indivisible part and directly contacts a portion of the upper surface of the first conductive material layer; and
a second first conductor comprising a second side part and a second lower part, the second side part directly contacting the first side part of the first first conductor, and the second lower part directly contacting the first lower part,
wherein the inorganic filler is surrounded by the second side part of the second first conductor.

9. The display panel of claim 1, wherein the circuit layer comprises:
a transistor arranged over the substrate, wherein the transistor comprises a semiconductor layer and a gate electrode; and
a capacitor comprising a first electrode and a second electrode which overlap each other,
wherein the first conductive material layer defines one of the semiconductor layer, the gate electrode, the first electrode, and the second electrode.

10. The display panel of claim 1, wherein a contact area of the second conductor and the first conductor has a closed-loop shape in a plan view.

11. The display panel of claim 1, wherein a width of an upper portion of the first contact hole measured by using a point, at which an upper surface and the inner wall of the first insulating layer meet each other, is greater than a width of an upper surface of the inorganic filler and is less than a width of a lower portion of the second contact hole measured by using a point, at which an inner wall of the second insulating layer and the upper surface of the first insulating layer meet each other.

12. An electronic apparatus comprising:
a display panel comprising a substrate, a light emitting diode arranged over the substrate, a circuit layer arranged between the substrate and the light emitting diode; and
a lower cover supporting the display panel,
wherein the circuit layer comprises:
a first conductive material layer arranged over the substrate;
a first insulating layer arranged over the first conductive material layer, wherein a first contact hole is defined in the first insulating layer to overlap a portion of an upper surface of the first conductive material layer;
a first conductor comprising a side part and a lower part, wherein the side part is on an inner wall of the first insulating layer defining the first contact hole, and the lower part is integrally formed with the side part as a single unitary indivisible part and directly contacts a portion of the upper surface of the first conductive material layer;
an inorganic filler arranged in a recess surrounded by the side part of the first conductor in the first contact hole, wherein the inorganic filler comprises an inorganic insulating material;
a second insulating layer arranged over the first insulating layer, wherein a second contact hole is defined in the second insulating layer to overlap the first contact hole; and
a second conductor directly contacting an upper surface of the side part of the first conductor through the second contact hole of the second insulating layer.

13. The electronic apparatus of claim 12, wherein
the second insulating layer comprises an inorganic insulating material, and
the inorganic insulating material of the second insulating layer is the same as the inorganic insulating material of the inorganic filler.

14. The electronic apparatus of claim 12, wherein the side part of the first conductor is in direct contact with the inner wall of the first insulating layer, and
a first point, at which the side part of the first conductor and the inner wall of the first insulating layer contact each other, is spaced apart by a first distance along the inner wall from a second point, at which the inner wall of the first insulating layer and an upper surface of the first insulating layer meet each other.

15. The electronic apparatus of claim 12, wherein the upper surface of the side part of the first conductor is located on an imaginary plane parallel to an upper surface of the substrate.

16. The electronic apparatus of claim 12, wherein the upper surface of the side part of the first conductor is inclined with respect to an imaginary plane parallel to an upper surface of the substrate.

17. The electronic apparatus of claim 12, wherein the circuit layer further comprises:
a transistor arranged over the substrate, wherein the transistor comprises a semiconductor layer and a gate electrode; and
a capacitor comprising a first electrode and a second electrode which overlap each other,
wherein the first conductive material layer defines one of the semiconductor layer, the gate electrode, the first electrode, and the second electrode.

18. An electronic apparatus comprising a display panel with a resolution of 1,500 ppi or greater,
wherein the display panel comprises a substrate, a light emitting diode arranged over the substrate, a circuit layer arranged between the substrate and the light emitting diode,
wherein the circuit layer comprises an interconnection structure,
wherein the interconnection structure comprises:
a first conductive material layer arranged over the substrate;
a first insulating layer arranged over the first conductive material layer, wherein a first contact hole is defined in the first insulating layer to overlap a portion of an upper surface of the first conductive material layer;
a first conductor electrically connected to the first conductive material layer, arranged in the first contact hole, and having a closed-loop shape in a plan view;
a second insulating layer arranged over the first insulating layer, wherein a second contact hole is defined in the second insulating layer; and
a second conductor directly contacting at least a portion of the first conductor through the second contact hole of the second insulating layer,
wherein area of a contact area of the second conductor and the first conductor is in a range of about 0.039 μm² to about 3.11 μm².

19. The electronic apparatus of claim 18, wherein the first conductor comprises:
a side part on an inner wall of the first insulating layer defining the first contact hole; and
a lower part integrally formed with the side part as a single unitary indivisible part and directly contacting a portion of the upper surface of the first conductive material layer, and
wherein the interconnection structure further comprises an inorganic filler arranged in a recess surrounded by the side part of the first conductor in the first contact hole, wherein the inorganic filler comprises an inorganic insulating material.

20. The electronic apparatus of claim 19, wherein the side part of the first conductor is in direct contact with the inner wall of the first insulating layer, and
a first point, at which the side part of the first conductor and the inner wall of the first insulating layer contact each other, is spaced apart by a first distance along the inner wall from a second point, at which the inner wall of the first insulating layer and an upper surface of the first insulating layer meet each other.

21. The electronic apparatus of claim 19, wherein the upper surface of the side part of the first conductor is located on an imaginary plane parallel to an upper surface of the substrate.

22. The electronic apparatus of claim 19, wherein the upper surface of the side part of the first conductor is inclined with respect to an imaginary plane parallel to an upper surface of the substrate.

23. The electronic apparatus of claim 19, wherein
the second insulating layer comprises an inorganic insulating material, and
the inorganic insulating material of the second insulating layer is the same as the inorganic insulating material of the inorganic filler.

24. The electronic apparatus of claim 18, wherein the circuit layer further comprises:
a transistor arranged over the substrate, wherein the transistor comprises a semiconductor layer and a gate electrode; and
a capacitor comprising a first electrode and a second electrode which overlap each other,
wherein the first conductive material layer defines one of the semiconductor layer, the gate electrode, the first electrode, and the second electrode.
